(19) United States
(12) Patent Application Publication
(10) Pub. No.: US 2024/0379280 A1
(43) Pub. Date: Nov. 14, 2024

(54) INDUCTOR COMPONENT AND INDUCTOR COMPONENT-EMBEDDED SUBSTRATE

(71) Applicant: Murata Manufacturing Co., Ltd., Nagaokakyo-shi (JP)

(72) Inventors: Nobuyoshi ADACHI, Nagaokakyo-shi (JP); Koshi HIMEDA, Nagaokakyo-shi (JP); Yoshimitsu USHIMI, Nagaokakyo-shi (JP); Kenji NISHIYAMA, Nagaokakyo-shi (JP)

(21) Appl. No.: 18/779,712

(22) Filed: Jul. 22, 2024

Related U.S. Application Data
(63) Continuation of application No. PCT/JP2023/028067, filed on Aug. 1, 2023.

(30) Foreign Application Priority Data
Aug. 9, 2022 (JP) 2022-127363

(51) Int. Cl. H01F 27/28; H01F 41/04

(52) U.S. Cl. CPC H01F 27/2804; H01F 41/041; H01F 2027/2809

(57) ABSTRACT

An inductor component includes an element body including a magnetic layer, a first coil and a second coil that are disposed adjacent to each other on a plane in the element body, and a first connection conductor that connects the first coil and the second coil. A first axis of the first coil and a second axis of the second coil are disposed parallel in a first direction that is orthogonal to the plane. A shortest distance between the first coil and the second coil is equal to or greater than a larger wiring width of a first wiring width of the first coil and a second wiring width of the second coil, and is equal to or less than an average value of a first diameter of a first smallest circle enclosing the first coil and a second diameter of a second smallest circle enclosing the second coil.

### CROSS REFERENCE TO RELATED APPLICATIONS

This application is a continuation of International Application No. PCT/JP2023/028067, filed Aug. 1, 2023, which claims priority to Japanese Patent Application No. 2022-127363, filed Aug. 9, 2022, the entire contents of each of which are hereby incorporated by reference in their entirety.

### TECHNICAL FIELD

The present disclosure relates to an inductor component and an inductor component-embedded substrate.

### BACKGROUND

In recent years, miniaturization of an electronic device such as a game machine and a cellular phone has accelerated, and accordingly, a demand for miniaturization and thinning of an inductor component mounted in the electronic device has increased. In addition, for an inductor component used for a power supply line that supplies power to a load such as a processor, there is a strong demand for thinning, for example, due to embedding in a substrate on which the load is mounted, because the inductor component can reduce power loss by being disposed in the vicinity of the load. With such a background, there is a demand for a thinner inductor component.

In the related art, an inductor component is described in Japanese Unexamined Patent Application Publication No. 2012-186440. The inductor component includes a plurality of magnetic layers and a wiring pattern formed on each magnetic layer.

However, in the inductor component in the related art, in order to obtain a high inductance value, it is necessary to increase the number of stacked wiring patterns. But in order to increase the number of stacked wiring patterns, the inductor component cannot be thinned to have a reduced overall size.

Moreover, in order to obtain a high inductance value while thinning the inductor component, it is considered to increase the number of stacked wiring patterns by reducing a thickness of the wiring pattern. However, when the thickness of the wiring pattern is reduced, a resistance value of the wiring pattern is increased, and power loss may be increased. On the other hand, it is considered to increase the number of stacked wiring patterns by reducing a thickness of a magnetic layer. However, when the thickness of the magnetic layer is reduced, the inductance value is decreased due to magnetism saturation in a case where a current is applied, and the DC superposition performance may deteriorate. In this way, in a case where an attempt is made to obtain a high inductance value while thinning the inductor component, the performance of the inductor component may deteriorate.

### SUMMARY

In view of the foregoing, the exemplary aspects of the present disclosure provide an inductor component and an inductor component-embedded substrate that obtains a high inductance value while thinning the inductor component while suppressing deterioration in performance.

Specifically, an exemplary aspect of the present disclosure provides an inductor component including an element body including a magnetic layer, a first coil and a second coil that are disposed on the same plane in the element body and are adjacent to each other, and a first connection conductor that connects the first coil and the second coil, in which an axis of the first coil and an axis of the second coil are orthogonal to the plane and are disposed parallel to each other. Moreover, when viewed in a first direction orthogonal to the plane, a shortest distance between the first coil and the second coil is equal to or greater than a largest wiring width among a wiring width of the first coil and a wiring width of the second coil, and is equal to or less than an average value of a diameter of a smallest circle enclosing the first coil and a diameter of a smallest circle enclosing the second coil.

In some exemplary embodiments, an inductor component is provided that includes an element body including a magnetic layer, a first coil and a second coil that are disposed on a plane in the element body and are adjacent to each other, and a first connection conductor that connects the first coil and the second coil. A first axis of the first coil and a second axis of the second coil are disposed parallel to each other in a first direction that is orthogonal to the plane. A shortest distance between the first coil and the second coil is equal to or greater than a larger wiring width of a first wiring width of the first coil and a second wiring width of the second coil, and is equal to or less than an average value of a first diameter of a first smallest circle enclosing the first coil and a second diameter of a second smallest circle enclosing the second coil.

For purposes of this disclosure, the wiring width of the first coil refers to an average width of a wiring of the first coil, and the wiring width of the second coil refers to an average width of a wiring of the second coil. The smallest circle enclosing the first coil refers to as a smallest enclosing circle of the first coil, and the smallest circle enclosing the second coil refers to as a smallest enclosing circle of the second coil.

According to the exemplary aspect, since the first coil and the second coil are provided, the inductance value can be improved. In this case, since the first coil and the second coil are disposed on the same plane in the element body and are adjacent to each other, and the axis of the first coil and the axis of the second coil are orthogonal to the plane and are disposed parallel to each other, the inductor component can be thinned.

In addition, since the first coil and the second coil are disposed on the same plane in the element body and are adjacent to each other, the inductance value can be improved while thinning the inductor component without reducing a wiring thickness of the coil. As a result, an increase in a resistance value of the coil according to the thickness of the wiring is suppressed, and an increase in power loss is suppressed. In addition, since the first coil and the second coil are disposed on the same plane in the element body and are adjacent to each other, the inductance value is improved while thinning the inductor component without reducing a thickness of the magnetic layer. As a result, a decrease in the inductance value due to magnetism saturation according to the thickness of the magnetic layer can be suppressed, and a deterioration in the DC superposition performance is suppressed. In this way, even when an attempt is made to obtain a high inductance value while thinning the inductor component, a deterioration in the performance of the inductor component can be suppressed.

Further, when viewed in the first direction, the shortest distance between the first coil and the second coil is equal to or greater than the largest wiring width among the wiring width of the first coil and the wiring width of the second coil, so that a possibility that the first coil and the second coil are electrically connected at positions other than end portions thereof is reduced.

In addition, when viewed in the first direction, the shortest distance between the first coil and the second coil is equal to or less than the average value of the diameter of the smallest circle enclosing the first coil and the diameter of the smallest circle enclosing the second coil, so that miniaturization can be achieved in a plane direction without requiring a space between the first coil and the second coil so as to place another coil adjacent.

According to an exemplary aspect of the inductor component, the first coil and the second coil each have a first coil conductor layer and a second coil conductor layer stacked in the first direction on the first coil conductor layer and electrically connected to the first coil conductor layer, the first coil conductor layers of the first coil and the second coil are disposed in the same layer, and the second coil conductor layers of the first coil and the second coil are disposed in the same layer, and the first connection conductor is connected in the same layer as the first coil conductor layers of the first coil and the second coil, or is connected in the same layer as the second coil conductor layers of the first coil and the second coil.

According to the exemplary embodiment, the first connection conductor is disposed in the same layer as the first coil conductor layer of the first coil or the first coil conductor layer of the second coil, or is disposed in the same layer as the second coil conductor layer of the first coil and the second coil conductor layer of the second coil, so that a length of the first connection conductor is shortened, and a series resistance is reduced.

According to an exemplary aspect of the inductor component, when viewed in the first direction, the first connection conductor is located in a region surrounded by a first smallest enclosing circle that is the smallest circle enclosing the first coil, a second smallest enclosing circle that is the smallest circle enclosing the second coil, a first common external tangent that is tangent to the first smallest enclosing circle and the second smallest enclosing circle, and a second common external tangent that is tangent to the first smallest enclosing circle and the second smallest enclosing circle.

According to the exemplary embodiment, the length of the first connection conductor can be shortened, and the series resistance is reduced.

According to an exemplary aspect of the inductor component, when viewed in the first direction, the first connection conductor is provided at such a position that the first connection conductor has the shortest distance.

According to the exemplary embodiment, the length of the first connection conductor is shortened, and the series resistance is reduced.

According to an exemplary aspect of the inductor component, the first coil and the second coil each have a first coil conductor layer and a second coil conductor layer stacked in the first direction on the first coil conductor layer and electrically connected to the first coil conductor layer, and when viewed in the first direction, the first coil conductor layer and the second coil conductor layer of the first coil each have an arc shape provided in a range where a central angle is 180° or more and 355° or less, and the first coil conductor layer and the second coil conductor layer of the second coil each have an arc shape provided in a range where a central angle is 180° or more and 355° or less.

According to the exemplary embodiment, by forming the coil conductor layer into an arc, any inductance value can be obtained over a wide range.

According to an exemplary aspect of the inductor component, when viewed in the first direction, a smallest circle enclosing the first coil conductor layer of the first coil and a smallest circle enclosing the first coil conductor layer of the second coil do not overlap each other, and a smallest circle enclosing the second coil conductor layer of the first coil and a smallest circle enclosing the second coil conductor layer of the second coil do not overlap each other.

According to the exemplary embodiment, cancellation of a magnetic flux of the first coil and a magnetic flux of the second coil is reduced.

According to an exemplary aspect of the inductor component, the inductor component includes a plurality of coils including at least the first coil and the second coil, the plurality of coils are disposed on the plane and are connected in series to each other to form one inductor group, the plurality of coils each have a plurality of coil conductor layers stacked in the first direction, and in each of the plurality of coils, the number of all the coil conductor layers included in one coil is smaller than the number of all the coil conductor layers included in the inductor group.

According to the exemplary embodiment, the inductor component can be thinned as compared with a case where the plurality of coils are stacked in the first direction in one inductor group.

According to an exemplary aspect of the inductor component, the inductor component further includes a third coil that is disposed on the plane in the element body and is adjacent to the second coil, and a second connection conductor that connects the second coil and the third coil, the axis of the second coil and an axis of the third coil are orthogonal to the plane and are disposed parallel to each other, and when viewed in the first direction, a shortest distance between the second coil and the third coil is equal to or greater than a largest wiring width among the wiring width of the second coil and a wiring width of the third coil, and is equal to or less than an average value of the diameter of the smallest circle enclosing the second coil and a diameter of a smallest circle enclosing the third coil.

According to the exemplary embodiment, since the third coil is provided, the inductance value can be improved. In this case, since the second coil and the third coil are disposed on the same plane in the element body and are adjacent to each other, and the axis of the second coil and the axis of the third coil are orthogonal to the plane and are disposed parallel to each other, the inductor component can be thinned.

In addition, since the second coil and the third coil are disposed on the same plane in the element body and are adjacent to each other, the inductance value can be improved while thinning the inductor component without reducing a wiring thickness of the coil. As a result, an increase in a resistance value of the coil according to the thickness of the wiring can be suppressed, and an increase in power loss can be suppressed. In addition, since the second coil and the third coil are disposed on the same plane in the element body and are adjacent to each other, the inductance value can be improved while thinning the inductor component without reducing a thickness of the magnetic layer. As a result, a decrease in the inductance value due to magnetism saturation according to the thickness of the magnetic layer can be suppressed, and a deterioration in the DC superposition performance can be suppressed. In this way, when an attempt is made to obtain a high inductance value while thinning the inductor component, a deterioration in the performance of the inductor component is suppressed.

Further, when viewed in the first direction, the shortest distance between the second coil and the third coil is equal to or greater than the largest wiring width among the wiring width of the second coil and the wiring width of the third coil, so that a possibility that the second coil and the third coil are electrically connected at positions other than end portions thereof is reduced.

In addition, since, when viewed in the first direction, the shortest distance between the second coil and the third coil is equal to or less than the average value of the diameter of the smallest circle enclosing the second coil and the diameter of the smallest circle enclosing the third coil, no space is required between the second coil and the third coil so as to place another coil adjacent. Therefore, miniaturization can be achieved in the plane direction.

According to an exemplary aspect of the inductor component, when viewed in the first direction, imaginary square lattice points are defined in which a line segment connecting a center of the smallest circle enclosing the first coil and a center of the smallest circle enclosing the second coil is used as one side, and a center of the smallest circle enclosing the third coil is located inside an imaginary circle that is centered on the square lattice point and of which a diameter is half of an average value of the diameter of the smallest circle enclosing the first coil, the diameter of the smallest circle enclosing the second coil, and the diameter of the smallest circle enclosing the third coil.

According to the exemplary embodiment, the first coil, the second coil, and the third coil can be efficiently disposed within a limited area, and the inductor component can be miniaturized.

According to an exemplary aspect of the inductor component, when viewed in the first direction, imaginary equilateral triangle lattice points are defined in which a line segment connecting a center of the smallest circle enclosing the first coil and a center of the smallest circle enclosing the second coil is used as one side, and a center of the smallest circle enclosing the third coil is located inside an imaginary circle that is centered on the equilateral triangle lattice point and of which a diameter is half of an average value of the diameter of the smallest circle enclosing the first coil, the diameter of the smallest circle enclosing the second coil, and the diameter of the smallest circle enclosing the third coil.

According to the exemplary embodiment, the first coil, the second coil, and the third coil can be efficiently disposed within a limited area, and the inductor component can be miniaturized.

According to an exemplary aspect of the inductor component, the second coil has a first coil conductor layer, a second coil conductor layer stacked in the first direction on the first coil conductor layer, and a via conductor that extends in the first direction and connects the first coil conductor layer and the second coil conductor layer, and when viewed in the first direction, a straight line connecting a center of the smallest circle enclosing the first coil and a center of the smallest circle enclosing the second coil is defined as a first straight line, a straight line connecting the center of the smallest circle enclosing the second coil and a center of the smallest circle enclosing the third coil is defined as a second straight line, a straight line that bisects an angle formed by the first straight line and the second straight line is defined as a third straight line, and the via conductor overlaps the third straight line.

According to the exemplary embodiment, the first coil, the second coil, and the third coil are efficiently disposed within a limited area, the inductor component is miniaturized, and the inductance value is improved. In addition, since the first coil conductor layer and the second coil conductor layer of the second coil can be disposed in a line-symmetrical manner with respect to the third straight line, warping due to thermal stress or the like is suppressed.

According to an exemplary aspect of the inductor component, the inductor component includes a plurality of coils including at least the first coil and the second coil, the plurality of coils are disposed on the plane and are connected in series to each other to form one inductor group, and when viewed in the first direction, assuming that an average value of diameters of smallest circles enclosing the coils is a first reference value and an average value of wiring widths of the coils is a second reference value, in a case where a first reference coil that has a smallest enclosing circle of which a diameter is 0.5 times the first reference value and which has a wiring width equal to the second reference value is defined, and a second reference coil that has a smallest enclosing circle of which a diameter is 2 times the first reference value and which has a wiring width equal to the second reference value is defined, an inductance value per unit area of each coil is larger than an inductance value per unit area of the first reference coil, and is larger than an inductance value per unit area of the second reference coil.

For purposes of this disclosure, it is noted that the inductance value per unit area of each coil is a value obtained by dividing the inductance value of each coil by an area of the smallest enclosing circle of each coil. The inductance value per unit area of the first reference coil is a value obtained by dividing the inductance value of the first reference coil by an area of the smallest enclosing circle of the first reference coil. The inductance value per unit area of the second reference coil is a value obtained by dividing the inductance value of the second reference coil by an area of the smallest enclosing circle of the second reference coil.

According to the exemplary embodiment, the inductance value per unit area of each coil can be increased, and the miniaturization of the inductor component and the improvement of the inductance value is achieved.

According to an exemplary aspect of an inductor component-embedded substrate, the inductor component-embedded substrate includes a substrate, and the inductor component which is embedded in the substrate.

According to the exemplary embodiment, the inductor component can be thinned without having the performance of the inductor component deteriorate.

With the inductor component and the inductor component-embedded substrate according to the aspect of the present disclosure, a high inductance value can be obtained while thinning the inductor component and suppressing deterioration in performance.

### BRIEF DESCRIPTION OF DRAWINGS

FIG. 1 is a perspective view showing a first exemplary embodiment of an inductor component.

FIG. 2 is a perspective view showing a plurality of coils of the inductor component.

FIG. 3 is a plan view showing the plurality of coils of the inductor component.

FIG. 4 is an exploded plan view of FIG. 3.

FIG. 5 is an enlarged view of a part of FIG. 3.

FIG. 6 is an exploded plan view of FIG. 5.

FIG. 7A is a cross-sectional view illustrating a manufacturing method of the inductor component.

FIG. 7B is a cross-sectional view illustrating a manufacturing method of the inductor component.

FIG. 7C is a cross-sectional view illustrating a manufacturing method of the inductor component.

FIG. 7D is a cross-sectional view illustrating a manufacturing method of the inductor component.

FIG. 7E is a cross-sectional view illustrating a manufacturing method of the inductor component.

FIG. 7F is a cross-sectional view illustrating a manufacturing method of the inductor component.

FIG. 7G is a cross-sectional view illustrating a manufacturing method of the inductor component.

FIG. 7H is a cross-sectional view illustrating a manufacturing method of the inductor component.

FIG. 7I is a cross-sectional view illustrating a manufacturing method of the inductor component.

FIG. 7J is a cross-sectional view illustrating a manufacturing method of the inductor component.

FIG. 7K is a cross-sectional view illustrating a manufacturing method of the inductor component.

FIG. 7L is a cross-sectional view illustrating a manufacturing method of the inductor component.

FIG. 7M is a cross-sectional view illustrating a manufacturing method of the inductor component.

FIG. 8 is an exploded plan view showing a first modification example of a first exemplary aspect of the inductor component.

FIG. 9 is a plan view showing a second modification example of the first exemplary aspect of the inductor component.

FIG. 10 is an exploded plan view showing a first modification example of a second exemplary aspect of the inductor component.

FIG. 11 is an exploded plan view showing a first modification example of a third exemplary aspect of the inductor component.

FIG. 12 is a plan view showing a fourth exemplary aspect of the inductor component.

FIG. 13 is a plan view showing a fifth exemplary aspect of the inductor component.

FIG. 14 is a plan view showing a first modification example of the fifth exemplary aspect of the inductor component.

FIG. 15 is a plan view showing a second modification example of the fifth exemplary aspect of the inductor component.

FIG. 16 is a plan view showing a sixth exemplary aspect of the inductor component.

FIG. 17 is a plan view showing a first modification example of the sixth exemplary aspect of the inductor component.

FIG. 18 is a plan view showing a second modification example of the sixth exemplary aspect of the inductor component.

FIG. 19 is a graph showing a relationship between a coil diameter and an inductance value density.

FIG. 20A is a plan view showing an example of a seventh exemplary aspect of the inductor component.

FIG. 20B is a plan view showing a comparative example of the seventh exemplary aspect of the inductor component.

FIG. 21 is a graph showing a relationship between a coil diameter and an inductance value density in the present example.

FIG. 22 is a plan view showing an eighth exemplary aspect of the inductor component.

FIG. 23 is an exploded plan view of FIG. 22.

FIG. 24 is an equivalent circuit diagram of a plurality of coils shown in FIG. 22.

FIG. 25 is a plan view showing a first modification example of the eighth exemplary aspect of the inductor component.

FIG. 26 is an exploded plan view of FIG. 25.

FIG. 27 is an equivalent circuit diagram of a plurality of coils shown in FIG. 25.

FIG. 28 is a plan view showing a second modification example of the eighth exemplary aspect of the inductor component.

FIG. 29 is an exploded plan view of FIG. 28.

FIG. 30 is an equivalent circuit diagram of a plurality of coils shown in FIG. 28.

FIG. 31 is a plan view showing a ninth exemplary aspect of the inductor component.

FIG. 32 is an exploded plan view of FIG. 31.

FIG. 33 is a plan view showing a first modification example of the ninth exemplary aspect of the inductor component.

FIG. 34 is an exploded plan view of FIG. 33.

FIG. 35 is a plan view showing another example of a tenth exemplary aspect of the inductor component.

FIG. 36 is a cross-sectional view showing one exemplary embodiment of an inductor component-embedded substrate.

### DETAILED DESCRIPTION OF EMBODIMENTS

Hereinafter, an inductor component according to some exemplary aspects of the present disclosure will be described in detail with reference to illustrated exemplary embodiments. Drawings include schematic views, and do not reflect actual dimensions or proportions in some cases.

### First Exemplary Embodiment

### [Summary Configuration]

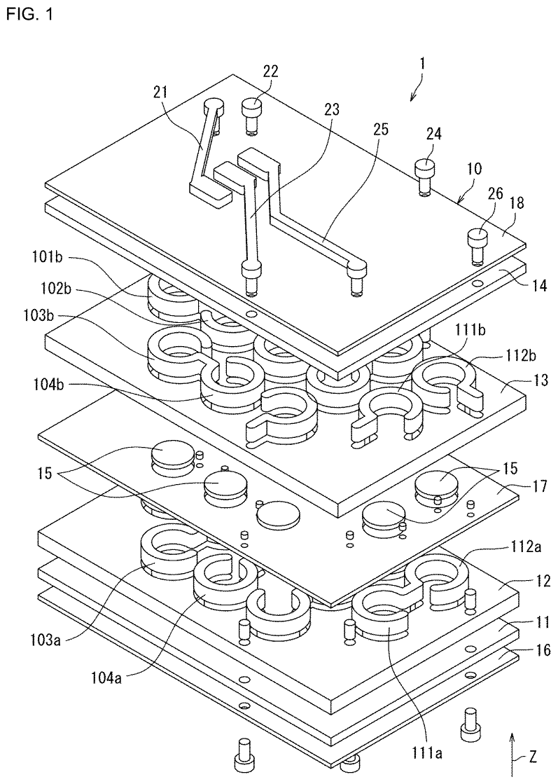

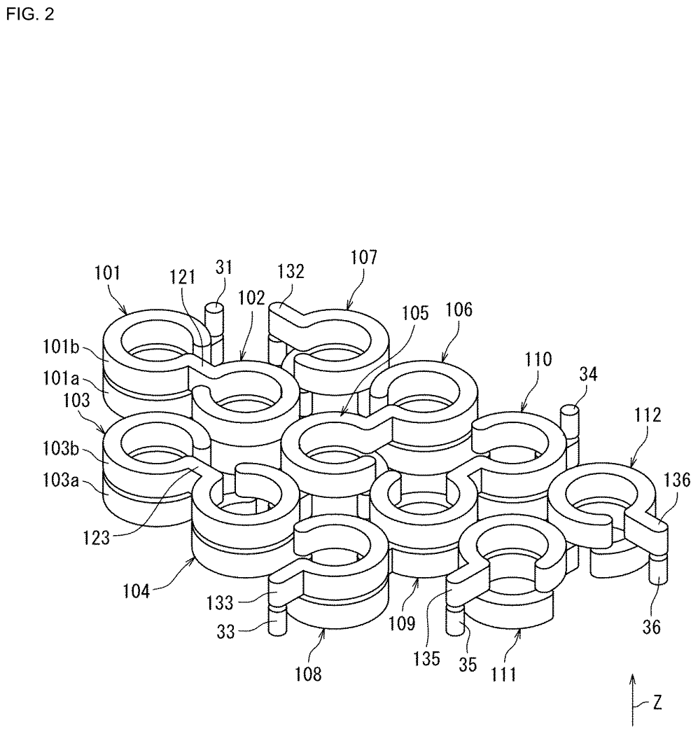

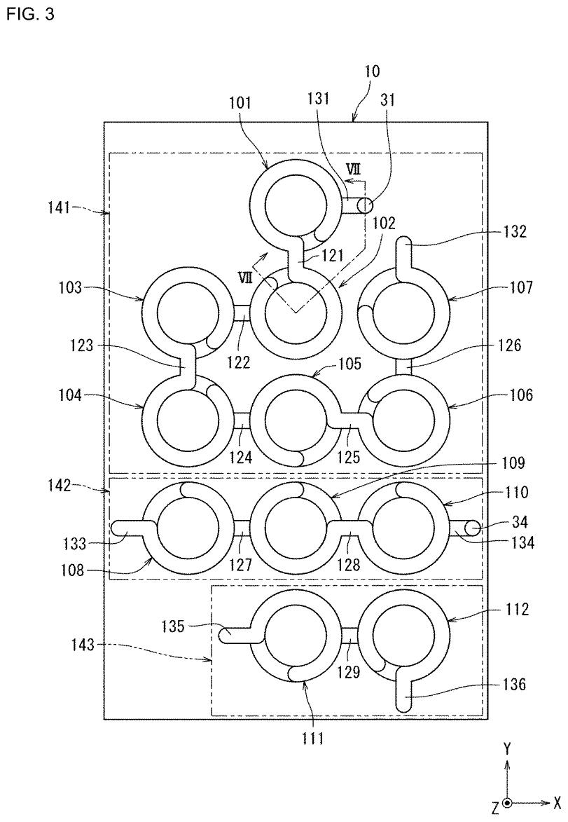

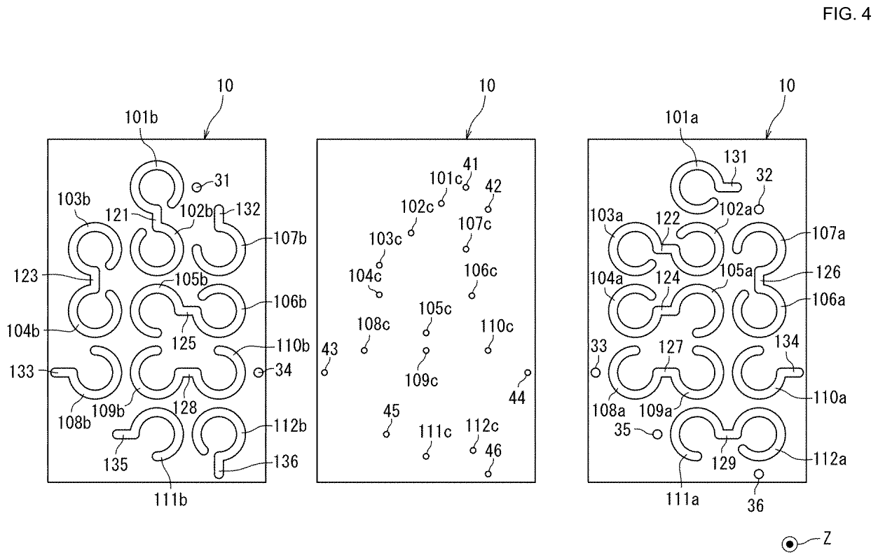

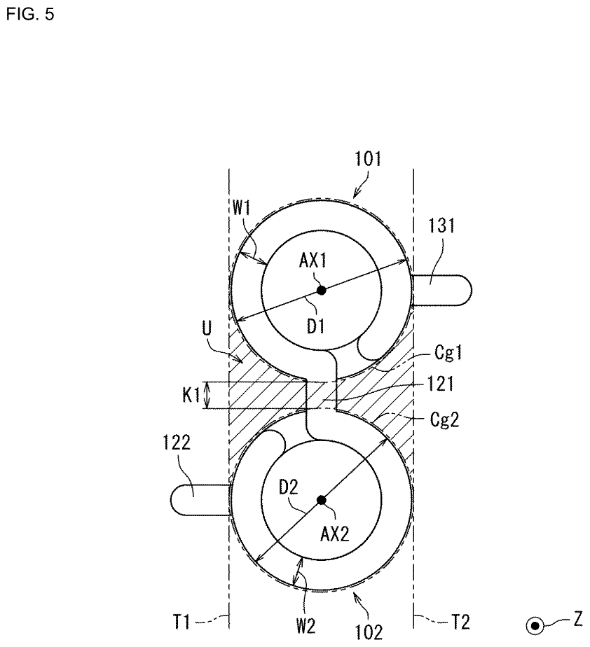

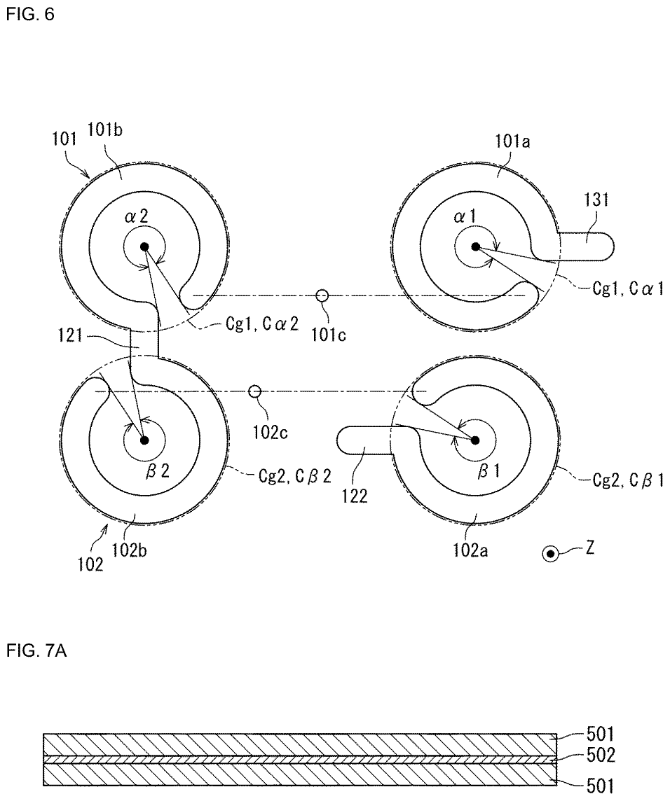

FIG. 1 is a perspective view showing a first embodiment of the inductor component. FIG. 2 is a perspective view showing a plurality of coils of the inductor component. FIG. 3 is a plan view showing the plurality of coils of the inductor component. FIG. 4 is an exploded plan view of FIG. 3. FIG. 5 is an enlarged view of a part of FIG. 3. FIG. 6 is an exploded plan view of FIG. 5. In FIGS. 3 and 4, an outer shape of an element body 10 is illustrated for convenience.

An inductor component 1 is mounted in, for example, an electronic device such as a personal computer, a DVD player, a digital camera, a TV, a cellular phone, and a car electronics, and is, for example, a component having a rectangular parallelepiped shape as a whole. Note that a shape of the inductor component 1 is not particularly limited, and may be cylindrical, polygonal columnar, conical trapezoidal, or polygonal trapezoidal.

As shown in FIGS. 1, 2, and 5, the inductor component 1 includes an element body 10, a first coil 101 and a second coil 102 disposed in the element body 10, and a first connection conductor 121 that connects an end portion of the first coil 101 and an end portion of the second coil 102.

The element body 10 includes a plurality of magnetic layers. In the present exemplary embodiment, the plurality of magnetic layers include a first magnetic layer 11, a second magnetic layer 12, a third magnetic layer 13, and a fourth magnetic layer 14. The first magnetic layer 11 to the fourth magnetic layer 14 are stacked in a first direction Z. Hereinafter, the first direction Z is also referred to as an upper side.

The first coil 101 and the second coil 102 are disposed on the same plane in the element body 10 and are adjacent to each other. In the present exemplary embodiment, the same plane is an upper surface of the first magnetic layer 11. The first direction is perpendicular to the plane.

The first coil 101 is wound spirally along a first axis AX1. The second coil 102 is wound spirally along a second axis AX2. The first axis AX1 and the second axis AX2 are orthogonal to the plane and are disposed parallel to each other. That is, the first axis AX1 and the second axis AX2 are disposed parallel to the first direction Z. The term “parallel” includes not only a case of being completely parallel but also a case of being substantially parallel.

The first connection conductor 121 is located between a first smallest enclosing circle Cg1, which is a smallest circle enclosing the first coil 101, and a second smallest enclosing circle Cg2, which is a smallest circle enclosing the second coil 102. In FIG. 5, the first smallest enclosing circle Cg1 and the second smallest enclosing circle Cg2 are shown by two-point chain lines, and for convenience, the first smallest enclosing circle Cg1 is shown to be spaced apart from the first coil 101, and the second smallest enclosing circle Cg2 is shown to be spaced apart from the second coil 102.

When viewed in the first direction Z, a first shortest distance K1 between the first coil 101 and the second coil 102 is equal to or greater than a largest wiring width among a first wiring width W1 of the first coil 101 and a second wiring width W2 of the second coil 102, and is equal to or less than an average value of a first diameter D1 of the first smallest enclosing circle Cg1 and a second diameter D2 of the second smallest enclosing circle Cg2. The first wiring width W1 is an average width of a wiring of the first coil 101. The second wiring width W2 is an average width of a wiring of the second coil 102. In the present exemplary embodiment, the first shortest distance K1 is a shortest distance between the end portion of the first coil 101 and the end portion of the second coil 102. The first wiring width W1 and the second wiring width W2 are the same, and the first diameter D1 and the second diameter D2 are the same. The first wiring width W1 and the second wiring width W2 may be different from each other, and the first diameter D1 and the second diameter D2 may be different from each other.

With the above configuration, since the first coil 101 and the second coil 102 are provided, an inductance value is improved. In this case, since the first coil 101 and the second coil 102 are disposed on the same plane in the element body 10 and are adjacent to each other, and the first axis AX1 of the first coil 101 and the second axis AX2 of the second coil 102 are orthogonal to the plane and are disposed parallel to each other, the inductor component 1 is thinned.

In addition, since the first coil 101 and the second coil 102 are disposed on the same plane in the element body 10 and are adjacent to each other, the inductance value is improved while thinning the inductor component 1 without reducing a wiring thickness of the coil as compared with a case where the first coil 101 and the second coil 102 are stacked in the first direction Z. As a result, an increase in a resistance value of the coil according to the thickness of the wiring is suppressed, and an increase in power loss is suppressed. In addition, since the first coil 101 and the second coil 102 are disposed on the same plane in the element body 10 and are adjacent to each other, the inductance value is improved while thinning the inductor component 1 without reducing a thickness of the magnetic layer as compared with a case where the first coil 101 and the second coil 102 are stacked in the first direction Z. As a result, a decrease in the inductance value due to magnetism saturation according to the thickness of the magnetic layer is suppressed, and a deterioration in the DC superposition performance is suppressed. In this way, even in a case where an attempt is made to obtain a high inductance value while thinning the inductor component 1, a deterioration in the performance of the inductor component 1 is suppressed.

Further, when viewed in the first direction Z, the first shortest distance K1 between the first coil 101 and the second coil 102 is equal to or greater than the largest wiring width among the first wiring width W1 of the first coil 101 and the second wiring width W2 of the second coil 102, so that a possibility that the first coil 101 and the second coil 102 are electrically connected at positions other than the end portions thereof is reduced.

In addition, when viewed in the first direction Z, the first shortest distance K1 between the first coil 101 and the second coil 102 is equal to or less than the average value of the first diameter D1 of the first smallest enclosing circle Cg1, which is the smallest circle enclosing the first coil 101, and the second diameter D2 of the second smallest enclosing circle Cg2, which is the smallest circle enclosing the second coil 102, so that miniaturization is achieved in a plane direction without requiring a space between the first coil 101 and the second coil 102 so as to place another coil adjacent.

The inductor component 1 may have at least one other coil in addition to the first coil 101 and the second coil 102, and in this case, at least one set of two adjacent coils need only satisfy the above-described configuration. According to an exemplary aspect, all sets of two adjacent coils need only satisfy the above-described configuration.

### First Exemplary Aspect

### (Configuration)

As shown in FIGS. 1, 2, and 3, the inductor component 1 includes the element body 10, first to twelfth coils 101 to 112 disposed in the element body 10, first to ninth connection conductors 121 to 129 disposed in the element body 10, first to sixth extended conductors 131 to 136 disposed in the element body 10, and first to sixth external conductors 21 to 26 provided on an upper surface of the element body 10.

The element body 10 includes the first to fourth magnetic layers 11 to 14, first to third insulating layers 16 to 18, and a magnetic path layer 15. The first insulating layer 16, the first magnetic layer 11, the second magnetic layer 12, the second insulating layer 17, the third magnetic layer 13, the fourth magnetic layer 14, and the third insulating layer 18 are disposed in this order along the first direction Z. The magnetic path layer 15 is disposed to penetrate an inside of the second insulating layer 17.

The first to fourth magnetic layers 11 to 14 and the magnetic path layer 15 are magnetic bodies and are made of, for example, a composite material of metal magnetic powder and an organic material. The metal magnetic powder is composed of, for example, an FeSi-based alloy such as FeSiCr, an FeCo-based alloy, an Fe-based alloy such as NiFe, or an amorphous alloy thereof. The organic material is composed of, for example, an epoxy resin, an acrylic resin, a phenol resin, a polyimide resin, a liquid crystal polymer, or a combination thereof.

Accordingly, the DC superposition characteristics is improved by the metal magnetic powder. In addition, when the inductor component 1 is embedded in, for example, a substrate, the resin elastically absorbs stress applied from an outside to reduce internal stress applied to the metal magnetic powder. Thereby, it is possible to prevent a decrease in the inductance value due to magnetostriction. The first to fourth magnetic layers 11 to 14 and the magnetic path layer 15 do not include an organic resin such as ferrite or a sintered body of magnetic powder in some cases.

The first to third insulating layers 16 to 18 are non-magnetic bodies and are made of, for example, a composite material of a non-magnetic inorganic material and an organic material or an organic material only. The organic material is composed of, for example, an epoxy resin, an acrylic resin, a phenol resin, a polyimide resin, a liquid crystal polymer, or a combination thereof. The non-magnetic inorganic material is composed of, for example, a filler such as silica. Accordingly, when the inductor component 1 is embedded in, for example, the substrate, the organic material of the insulator 60 elastically absorbs the stress applied from the outside to reduce the internal stress applied to the metal magnetic powder. Thereby, it is possible to prevent the decrease in the inductance value due to the magnetostriction.

The first to third insulating layers 16 to 18 may be a sintered body such as glass or alumina, a thin film such as a silicon oxide film, a silicon nitride film, or a silicon oxynitride film, or the like. In addition, the first to third insulating layers 16 to 18 may be a magnetic body instead of a non-magnetic body.

The first to twelfth coils 101 to 112 are embedded in the second magnetic layer 12 and the third magnetic layer 13. The first to twelfth coils 101 to 112 are disposed on the same plane (on the upper surface of the first magnetic layer 11) in the element body 10 and are adjacent to each other. Axes of the first to twelfth coils 101 to 112 are orthogonal to the plane and are disposed parallel to each other. As a result, as described in the above-described schematic configuration, it is possible to obtain a high inductance value while thinning the inductor component 1 while suppressing the deterioration in the performance of the inductor component 1.

Specifically, the first coil 101, the second coil 102, the third coil 103, the fourth coil 104, the fifth coil 105, the sixth coil 106, and the seventh coil 107 are connected in series in this order to form a first inductor group 141. The eighth coil 108, the ninth coil 109, and the tenth coil 110 are connected in series in this order to form a second inductor group 142. The eleventh coil 111 and the twelfth coil 112 are connected in series in this order to form a third inductor group 143.

The first connection conductor 121 connects the end portion of the first coil 101 and the end portion of the second coil 102. The second connection conductor 122 connects the end portion of the second coil 102 and the end portion of the third coil 103. The third connection conductor 123 connects the end portion of the third coil 103 and an end portion of the fourth coil 104. The fourth connection conductor 124 connects the end portion of the fourth coil 104 and an end portion of the fifth coil 105. The fifth connection conductor 125 connects the end portion of the fifth coil 105 and an end portion of the sixth coil 106. The sixth connection conductor 126 connects the end portion of the sixth coil 106 and an end portion of the seventh coil 107. The seventh connection conductor 127 connects an end portion of the eighth coil 108 and an end portion of the ninth coil 109. The eighth connection conductor 128 connects the end portion of the ninth coil 109 and an end portion of the tenth coil 110. The ninth connection conductor 129 connects an end portion of the eleventh coil 111 and the end portion of the twelfth coil 112.

The first extended conductor 131 is connected to the end portion of the first coil 101. The second extended conductor 132 is connected to the end portion of the seventh coil 107. The third extended conductor 133 is connected to the end portion of the eighth coil 108. The fourth extended conductor 134 is connected to the end portion of the tenth coil 110. The fifth extended conductor 135 is connected to the end portion of the eleventh coil 111. The sixth extended conductor 136 is connected to the end portion of the twelfth coil 112.

The first to twelfth coils 101 to 112, the first to ninth connection conductors 121 to 129, and the first to sixth extended conductors 131 to 136 are made of a conductive material, and are made of, for example, a metal material with a low electric resistance, such as Cu, Ag, Au, Fe, or an alloy containing these.

The first to sixth external conductors 21 to 26 are provided on the third insulating layer 18. The first to sixth external conductors 21 to 26 are made of, for example, the same conductive material as the first to twelfth coils 101 to 112.

Specifically, the first external conductor 21 is electrically connected to the first extended conductor 131. The second external conductor 22 is electrically connected to the second extended conductor 132. The third external conductor 23 is electrically connected to the third extended conductor 133. The fourth external conductor 24 is electrically connected to the fourth extended conductor 134. The fifth external conductor 25 is electrically connected to the fifth extended conductor 135. The sixth external conductor 26 is electrically connected to the sixth extended conductor 136.

Other external conductors similar to the first to sixth external conductors 21 to 26 may be provided on a lower surface of the element body 10 (a lower surface of the first insulating layer 16), and the other external conductors may be electrically connected to the first to sixth external conductors 21 to 26.

As shown in FIGS. 3 and 4, the first coil 101 has a first coil conductor layer 101a (also referred to as first coil conductor layer portion) and a second coil conductor layer 101b (also referred to as second coil conductor layer portion) that is stacked in the first direction Z on the first coil conductor layer 101a and is electrically connected to the first coil conductor layer 101a with a via conductor 101c interposed therebetween. Similarly, the second coil 102 has a first coil conductor layer 102a and a second coil conductor layer 102b that is electrically connected to the first coil conductor layer 102a with a via conductor 102c interposed therebetween.

The first coil conductor layer 101a of the first coil 101 and the first coil conductor layer 102a of the second coil 102 are disposed in the same layer, and the second coil conductor layer 101b of the first coil 101 and the second coil conductor layer 102b of the second coil 102 are disposed in the same layer. The first connection conductor 121 is connected in the same layer as the second coil conductor layer 101b of the first coil 101 and the second coil conductor layer 102b of the second coil 102.

With the above configuration, since the first connection conductor 121 is disposed in the same layer as the second coil conductor layer 101b of the first coil 101 and the second coil conductor layer 102b of the second coil 102, a length of the first connection conductor 121 can be shortened, and the series resistance is reduced. The first connection conductor 121 may be connected in the same layer as the first coil conductor layer 101a of the first coil 101 and the first coil conductor layer 102a of the second coil 102.

Similarly, the third coil 103 has a first coil conductor layer 103a, a second coil conductor layer 103b, and a via conductor 103c. The fourth coil 104 has a first coil conductor layer 104a, a second coil conductor layer 104b, and a via conductor 104c. The fifth coil 105 has a first coil conductor layer 105a, a second coil conductor layer 105b, and a via conductor 105c. The sixth coil 106 has a first coil conductor layer 106a, a second coil conductor layer 106b, and a via conductor 106c. The seventh coil 107 has a first coil conductor layer 107a, a second coil conductor layer 107b, and a via conductor 107c. The eighth coil 108 has a first coil conductor layer 108a, a second coil conductor layer 108b, and a via conductor 108c. The ninth coil 109 has a first coil conductor layer 109a, a second coil conductor layer 109b, and a via conductor 109c. The tenth coil 110 has a first coil conductor layer 110a, a second coil conductor layer 110b, and a via conductor 110c. The eleventh coil 111 has a first coil conductor layer 111a, a second coil conductor layer 111b, and a via conductor 111c. The twelfth coil 112 has a first coil conductor layer 112a, a second coil conductor layer 112b, and a via conductor 112c.

Similarly, the second connection conductor 122 is connected in the same layer as the first coil conductor layer 102a and the first coil conductor layer 103a. The third connection conductor 123 is connected in the same layer as the second coil conductor layer 103b and the second coil conductor layer 104b. The fourth connection conductor 124 is connected in the same layer as the first coil conductor layer 104a and the first coil conductor layer 105a. The fifth connection conductor 125 is connected in the same layer as the second coil conductor layer 105b and the second coil conductor layer 106b. The sixth connection conductor 126 is connected in the same layer as the first coil conductor layer 106a and the first coil conductor layer 107a. The seventh connection conductor 127 is connected in the same layer as the first coil conductor layer 108a and the first coil conductor layer 109a. The eighth connection conductor 128 is connected in the same layer as the second coil conductor layer 109b and the second coil conductor layer 110b. The ninth connection conductor 129 is connected in the same layer as the first coil conductor layer 111a and the first coil conductor layer 112a.

The first coil conductor layers 101a to 112a are embedded in the second magnetic layer 12, and the second coil conductor layers 101b to 112b are embedded in the third magnetic layer 13. The first coil conductor layers 101a to 112a are disposed on the upper surface of the first magnetic layer 11, and the second coil conductor layers 101b to 112b are disposed on an upper surface of the second insulating layer 17.

The magnetic path layer 15 is disposed between the first coil conductor layers 101a to 112a and the second coil conductor layers 101b to 112b. The magnetic path layer 15 is provided at a position corresponding to an inner magnetic path of each of the coils 101 to 112.

As shown in FIG. 4, the first extended conductor 131 is connected to a first columnar conductor 31 with a first via conductor 41 interposed therebetween. The second extended conductor 132 is connected to a second columnar conductor 32 with a second via conductor 42 interposed therebetween. The third extended conductor 133 is connected to a third columnar conductor 33 with a third via conductor 43 interposed therebetween. The fourth extended conductor 134 is connected to a fourth columnar conductor 34 with a fourth via conductor 44 interposed therebetween. The fifth extended conductor 135 is connected to a fifth columnar conductor 35 with a fifth via conductor 45 interposed therebetween. The sixth extended conductor 136 is connected to a sixth columnar conductor 36 with a sixth via conductor 46 interposed therebetween.

The first and fourth extended conductors 131 and 134 and the second, third, fifth, and sixth columnar conductors 32, 33, 35, and 36 are disposed in the same layer as the first coil conductor layers 101a to 112a. The second, third, fifth, and sixth extended conductors 132, 133, 135, and 136 and the first and fourth columnar conductors 31 and 34 are disposed in the same layer as the second coil conductor layers 101b to 112b.

As shown in FIGS. 5 and 6, in the first coil 101, the first coil conductor layer 101a and the second coil conductor layer 101b match each other in a circular shape when viewed in the first direction Z. That is, when viewed from the first direction Z, the first smallest enclosing circle Cg1 matches a smallest enclosing circle Cα1 of the first coil conductor layer 101a and a smallest enclosing circle Cα2 of the second coil conductor layer 101b. The first coil conductor layer 101a and the second coil conductor layer 101b are located inside the first smallest enclosing circle Cg1. The first axis AX1 matches a center of the first smallest enclosing circle Cg1.

In the second coil 102, the first coil conductor layer 102a and the second coil conductor layer 102b match each other in a circular shape when viewed in the first direction Z. That is, when viewed from the first direction Z, the second smallest enclosing circle Cg2 matches a smallest enclosing circle Cβ1 of the first coil conductor layer 102a and a smallest enclosing circle Cβ2 of the second coil conductor layer 102b. The first coil conductor layer 102a and the second coil conductor layer 102b are located inside the second smallest enclosing circle Cg2. The second axis AX2 matches a center of the second smallest enclosing circle Cg2.

When viewed in the first direction Z, the first shortest distance K1 between the first coil 101 and the second coil 102 is equal to or greater than the largest wiring width among the first wiring width W1 of the first coil 101 and the second wiring width W2 of the second coil 102, and is equal to or less than the average value of the first diameter D1 of the first smallest enclosing circle Cg1 and the second diameter D2 of the second smallest enclosing circle Cg2.

The first shortest distance K1 is the shortest distance between the end portion of the first coil 101 and the end portion of the second coil 102. That is, the first shortest distance K1 is the shortest distance of the first connection conductor 121.

The first wiring width W1 is the average width of the wiring of the first coil 101. Specifically, the first wiring width W1 is an average value of the average width of the wiring of the first coil conductor layer 101a and the average width of the wiring of the second coil conductor layer 101b. According to an exemplary aspect, the wiring widths of the first coil conductor layer 101a and the second coil conductor layer 101b are the same.

The second wiring width W2 is an average width of a wiring of the second coil 102. Specifically, the second wiring width W2 is an average value of the average width of the wiring of the first coil conductor layer 102a and the average width of the wiring of the second coil conductor layer 102b. According to an exemplary aspect, the wiring widths of the first coil conductor layer 102a and the second coil conductor layer 102b are the same. According to an exemplary aspect, the first wiring width W1 and the second wiring width W2 are the same.

The first diameter D1 of the first smallest enclosing circle Cg1 is the same as a diameter of the smallest enclosing circle Cα1 of the first coil conductor layer 101a and a diameter of the smallest enclosing circle Cα2 of the second coil conductor layer 101b. The second diameter D2 of the second smallest enclosing circle Cg2 is the same as a diameter of the smallest enclosing circle Cβ1 of the first coil conductor layer 102a and a diameter of the smallest enclosing circle Cβ2 of the second coil conductor layer 102b. According to an exemplary aspect, the first diameter D1 and the second diameter D2 are the same.

With the above configuration, when viewed in the first direction Z, the first shortest distance K1 is equal to or greater than the largest wiring width among the first wiring width W1 of the first coil 101 and the second wiring width W2 of the second coil 102, so that a possibility that the first coil 101 and the second coil 102 are electrically connected at positions other than the end portions thereof is reduced. In addition, when viewed in the first direction Z, the first shortest distance K1 is equal to or less than the average value of the first diameter D1 of the first smallest enclosing circle Cg1 and the second diameter D2 of the second smallest enclosing circle Cg2, so that miniaturization is achieved in the plane direction without requiring a space between the first coil 101 and the second coil 102 so as to place another coil adjacent.

At least one set of two adjacent coils among the first to twelfth coils 101 to 112 need only satisfy the above-described configuration. According to an exemplary aspect, all sets of two adjacent coils need only satisfy the above-described configuration.

As shown in FIG. 5, when viewed in the first direction Z, the first connection conductor 121 is located in a region U surrounded by the first smallest enclosing circle Cg1, the second smallest enclosing circle Cg2, a first common external tangent T1 that is tangent to the first smallest enclosing circle Cg1 and the second smallest enclosing circle Cg2, and a second common external tangent T2 that is tangent to the first smallest enclosing circle Cg1 and the second smallest enclosing circle Cg2. In FIG. 5, the first common external tangent T1 and the second common external tangent T2 are shown by two-point chain lines, and the region U is shown by hatching. Accordingly, the length of the first connection conductor 121 is shortened, and the series resistance is reduced.

According to an exemplary aspect, when viewed in the first direction Z, the first connection conductor 121 is provided at such a position that the first connection conductor 121 has the first shortest distance K1. Accordingly, the length of the first connection conductor 121 can be further shortened, and the series resistance is further reduced.

At least one connection conductor among the first to ninth connection conductors 121 to 129 need only satisfy the above-described configuration. According to an exemplary aspect, all the connection conductors need only satisfy the above-described configuration.

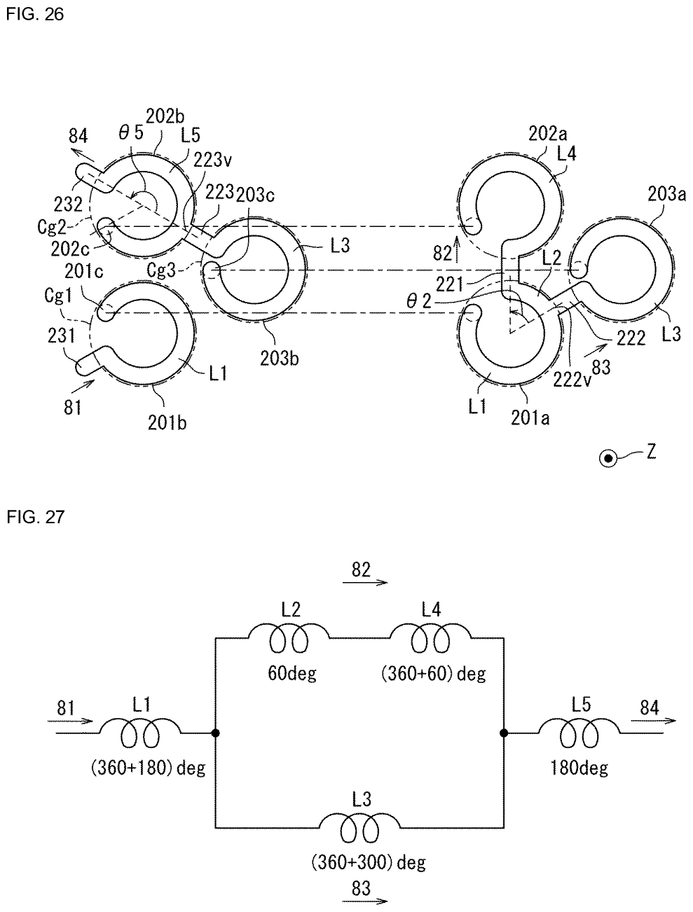

In addition, in the example described above, the first to ninth connection conductors 121 to 129 connect the end portions of the two adjacent coils, but the connection conductors need only connect one of the two adjacent coils and the other coil. For example, the connection conductor may connect the end portion of one coil to a portion of the coil conductor layer of the other coil other than the end portion (see FIG. 26 and the like to be described below).

### (Manufacturing Method)

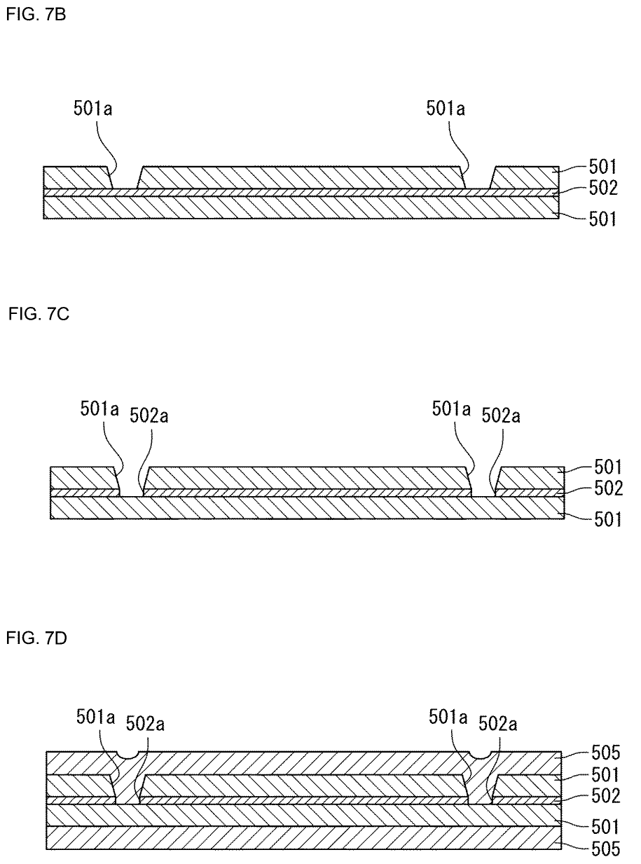

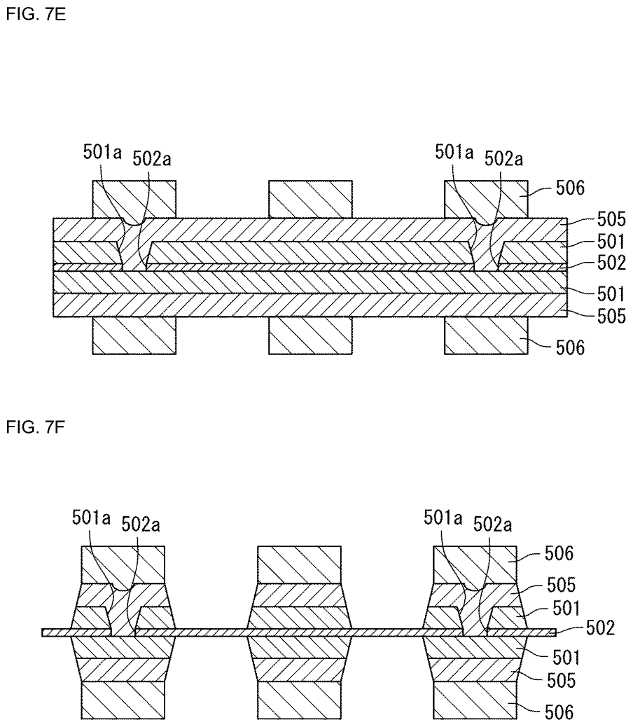

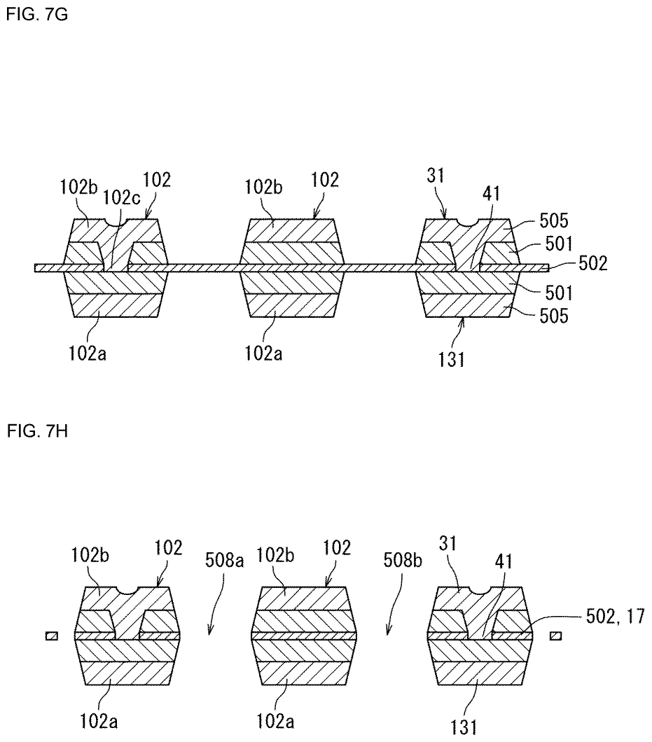

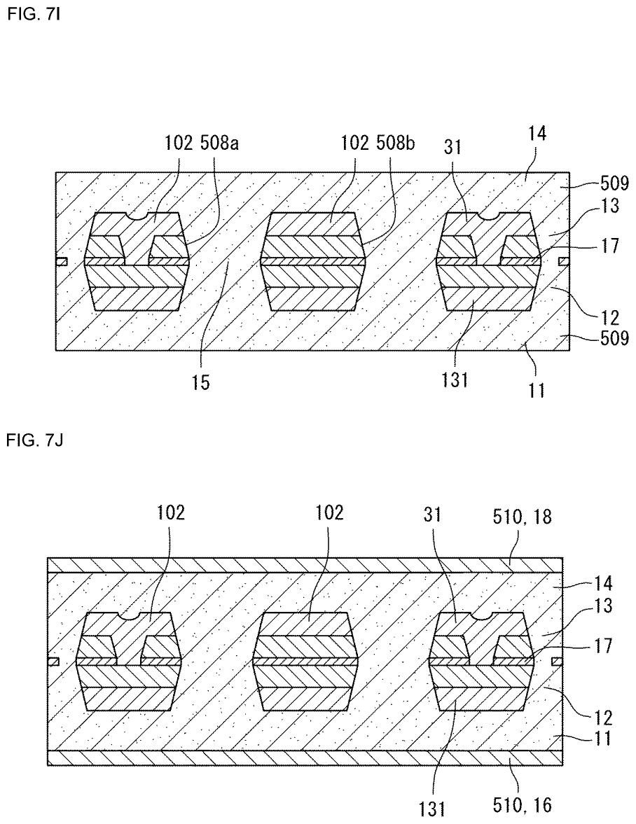

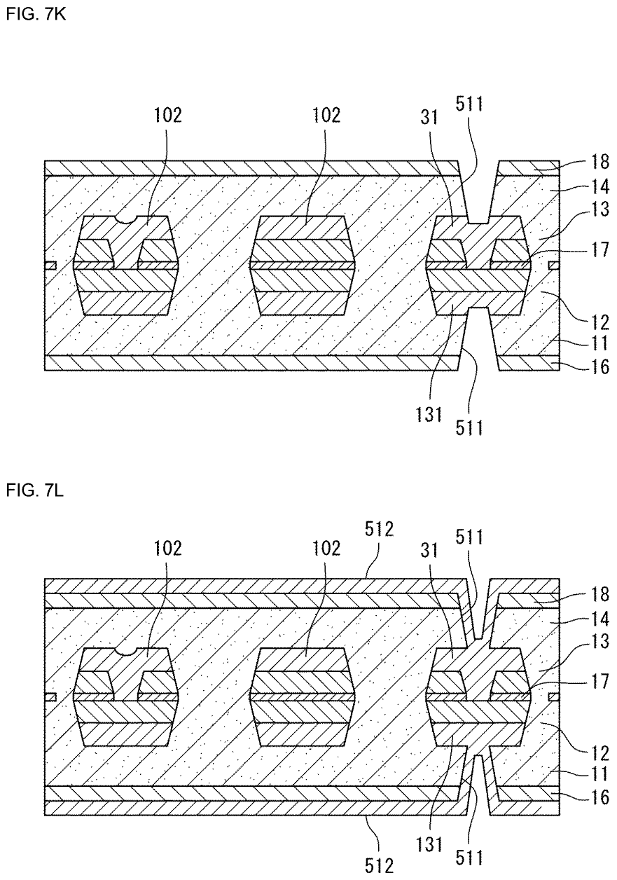

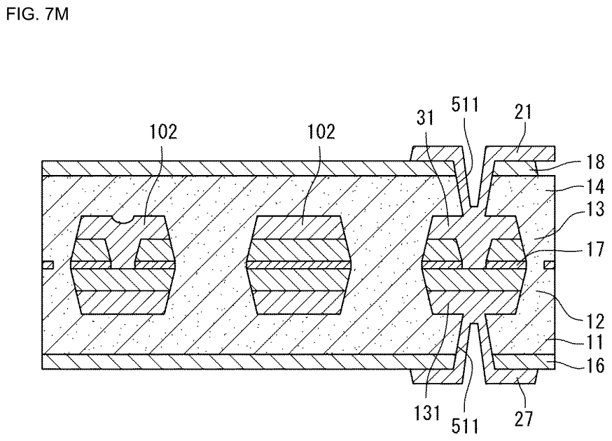

Next, a manufacturing method of the inductor component 1 will be described. FIGS. 7A to 7M correspond to a cross section taken along line VII-VII of FIG. 3.

As shown in FIG. 7A, two copper foils 501 are prepared, and the two copper foils 501 are bonded to each other using an adhesive layer 502 to form a substrate whose upper and lower surfaces are copper foils. As shown in FIG. 7B, the copper foil 501 on the upper side is patterned using a photoresist to form a copper foil cavity 501a by etching.

As shown in FIG. 7C, the adhesive layer 502 exposed from the copper foil cavity 501a is removed by laser processing to form an adhesive layer cavity 502a. As shown in FIG. 7D, a copper plating film 505 is formed on the upper and lower copper foils 501 by electroless or electrolytic plating. In this case, the copper foil cavity 501a and the adhesive layer cavity 502a are filled with the copper plating film 505. In the copper plating film 505, a recess may be formed at a position overlapping the copper foil cavity 501a and the adhesive layer cavity 502a.

As shown in FIG. 7E, a patterned resist 506 is formed on the upper and lower copper plating films 505. In this case, the resist 506 is provided at a position overlapping the copper foil cavity 501a and the adhesive layer cavity 502a. As shown in FIG. 7F, the copper plating film 506 is etched using the resist 506, and as shown in FIG. 7G, the resist 506 is peeled off to form a coil pattern. Specifically, the second coil 102 including the first coil conductor layer 102a, the second coil conductor layer 102b, and the via conductor 102c, the first extended conductor 131, the first via conductor 41, and the first columnar conductor 31 are formed.

As shown in FIG. 7H, in the adhesive layer 502, portions corresponding to an inner magnetic path 508a and an outer magnetic path 508b of the coil are removed by laser processing. The second insulating layer 17 is formed by the adhesive layer 502.

As shown in FIG. 7I, a magnetic sheet 509 made of a composite material of the metal magnetic powder and the resin material is formed above and below the coil while filling a space between the coils by vacuum pressing or vacuum lamination. The first to fourth magnetic layers 11 to 14 and the magnetic path layer 15 are formed by the magnetic sheet 509. The magnetic sheet 509 may be formed on each of the upper and lower surfaces, or may be formed on both the upper and lower surfaces simultaneously.

As shown in FIG. 7J, an insulating resin layer 510 such as ABF is formed on both the upper and lower surfaces. The first insulating layer 16 and the third insulating layer 18 are formed by the insulating resin layer 510. As shown in FIG. 7K, in the first insulating layer 16 and the third insulating layer 18 and the first magnetic layer 11 and the fourth magnetic layer 14, a via hole 511 is formed at positions corresponding to the first extended conductor 131 and the first columnar conductor 31 by laser processing, drilling, or the like.

As shown in FIG. 7L, a metal film 512 is formed on an inner surface of the via hole 511, the first insulating layer 16, and the third insulating layer 18 by electroless or electrolytic plating, and is connected to the first extended conductor 131 and the first columnar conductor 31. Although the plating in the via hole 511 may be either conformal plating or filling plating, filling plating is used, in some exemplary embodiments, when a large current is applied.

As shown in FIG. 7M, the metal film 512 is etched using a photoresist to form the first external conductor 21 on the upper side and the seventh external conductor 27 on the lower side. The external conductor may be coated with plating of Ni, Au, or the like. The external conductors may be formed on only one of the upper and lower surfaces, or may be formed on both the upper and lower surfaces. Thereafter, the obtained product is cut with a dicing machine into individual pieces to manufacture the inductor component 1 shown in FIG. 1.

### First Modification Example

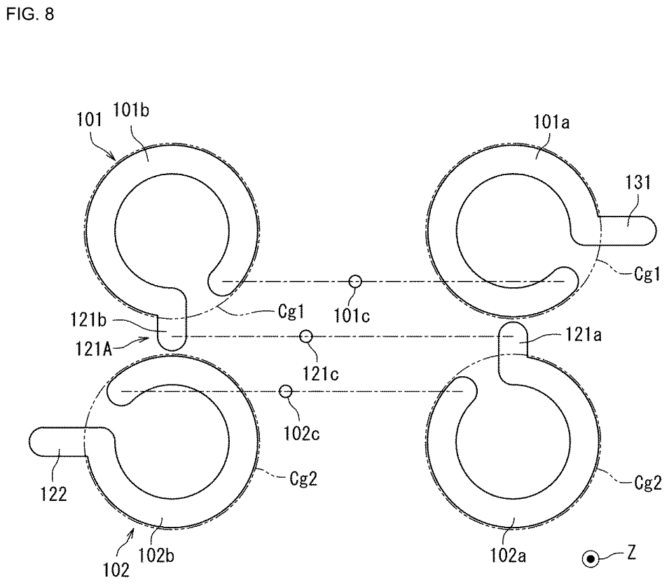

FIG. 8 is an exploded plan view showing a first modification example of a first form of the inductor component. FIG. 8 is a view corresponding to FIG. 6. The first modification example is different from the form shown in FIG. 6 in the configuration of the first connection conductor. The different configuration will be described below.

As shown in FIG. 8, a first connection conductor 121A has a first portion 121a, a second portion 121b, and a via portion 121c. The first portion 121a is connected in the same layer as the first coil conductor layer 102a of the second coil 102. The second portion 121b is connected in the same layer as the second coil conductor layer 101b of the first coil 101. The via portion 121c is disposed in the same layer as the via conductors 101c and 102c, and connects the first portion 121a and the second portion 121b.

With the above configuration, since the first connection conductor 121A is divided into upper and lower layers, a path of the current flowing through the first coil 101 and the second coil 102 can be easily changed. Specifically, by dividing the first connection conductor 121A into upper and lower layers, the second connection conductor 122 can be connected to the second coil conductor layer 102b of the second coil 102. In addition, a length of the first connection conductor 121A can be made longer without changing the shortest distance between the first coil 101 and the second coil 102, and the inductance value is easily changed.

### Second Modification Example

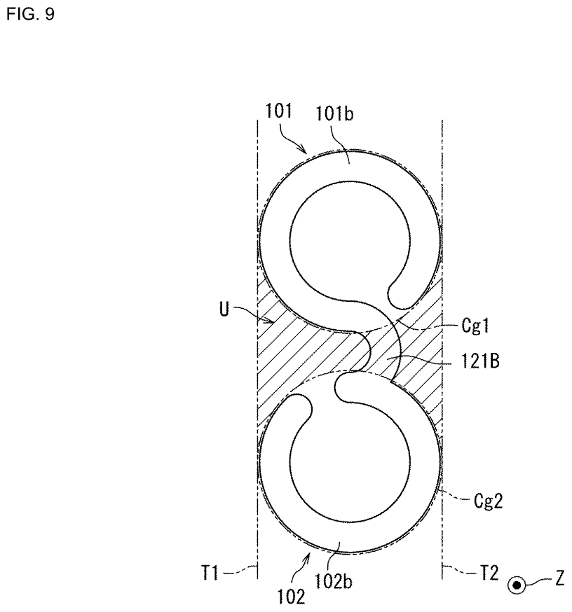

FIG. 9 is a plan view showing a second modification example of the first form of the inductor component. FIG. 9 is a view corresponding to FIG. 6. The second modification example is different from the form shown in FIG. 6 in the configuration of the first connection conductor. The different configuration will be described below.

As shown in FIG. 9, a first connection conductor 121B is not a straight line but a curve. Accordingly, a length of the first connection conductor 121B can be made longer without changing the shortest distance between the first coil 101 and the second coil 102, and the inductance value is easily changed.

When viewed in the first direction Z, the first connection conductor 121 is not provided at such a position that the first connection conductor 121 has the first shortest distance K1. However, when viewed in the first direction Z, the first connection conductor 121B is located in the region U surrounded by the first smallest enclosing circle Cg1, the second smallest enclosing circle Cg2, the first common external tangent T1 that is tangent to the first smallest enclosing circle Cg1 and the second smallest enclosing circle Cg2, and the second common external tangent T2 that is tangent to the first smallest enclosing circle Cg1 and the second smallest enclosing circle Cg2. Accordingly, the length of the first connection conductor 121 can be shortened, and the series resistance can be reduced.

### Second Exemplary Aspect

### (Configuration)

As shown in FIG. 6, when viewed in the first direction Z, the first coil conductor layer 101a of the first coil 101 has an arc shape provided in a range where a first central angle α1 is 180° or more and 355° or less. The first central angle α1 refers to an angle between two tangents when a tangent that is tangent to each of both end portions of the first coil conductor layer 101a is drawn from a center of the first smallest enclosing circle Cα1 enclosing the first coil conductor layer 101a having an arc shape, when viewed in the first direction Z.

Similarly, when viewed in the first direction Z, the second coil conductor layer 101b of the first coil 101 has an arc shape provided in a range where a second central angle α2 is 180° or more and 355° or less. The second central angle α2 refers to an angle between two tangents when a tangent that is tangent to each of both end portions of the second coil conductor layer 101b is drawn from a center of the second smallest enclosing circle Cα2 enclosing the second coil conductor layer 101b having an arc shape, when viewed in the first direction Z.

Specifically, the first central angle α1 is, for example, 315°, and the second central angle α2 is, for example, 315°. Here, the first smallest enclosing circle Cα1 and the second smallest enclosing circle Cα2 match the first smallest enclosing circle Cg1.

Similarly, when viewed in the first direction Z, the first coil conductor layer 102a of the second coil 102 has an arc shape provided in a range where a first central angle β1 is 180° or more and 355° or less. The first central angle β1 refers to an angle between two tangents when a tangent that is tangent to each of both end portions of the first coil conductor layer 102a is drawn from a center of the first smallest enclosing circle CO 1 enclosing the first coil conductor layer 102a having an arc shape, when viewed in the first direction Z.

When viewed in the first direction Z, the second coil conductor layer 102b of the second coil 102 has an arc shape provided in a range where a second central angle 32 is 180° or more and 355° or less. The second central angle β2 refers to an angle between two tangents when a tangent that is tangent to each of both end portions of the second coil conductor layer 102b is drawn from a center of the second smallest enclosing circle Cβ2 enclosing the second coil conductor layer 102b having an arc shape, when viewed in the first direction Z.

Specifically, the first central angle β1 is, for example, 315°, and the second central angle β2 is, for example, 315°. Here, the first smallest enclosing circle Cβ1 and the second smallest enclosing circle Cβ2 match the second smallest enclosing circle Cg2.

When viewed in the first direction Z, the first smallest enclosing circle Cα1, which is the smallest circle enclosing the first coil conductor layer 101a of the first coil 101, and the first smallest enclosing circle Cβ1, which is the smallest circle enclosing the first coil conductor layer 102a of the second coil 102, do not overlap each other and are spaced apart from each other. In addition, when viewed in the first direction Z, the second smallest enclosing circle Cα2, which is the smallest circle enclosing the second coil conductor layer 101b of the first coil 101, and the second smallest enclosing circle Cβ2, which is the smallest circle enclosing the second coil conductor layer 102b of the second coil 102, do not overlap each other and are spaced apart from each other.

With the above configuration, by forming the first coil conductor layers 101a and 102a and the second coil conductor layers 101b and 102b into an arc, any inductance value is obtained over a wide range. In addition, when viewed in the first direction Z, the first smallest enclosing circle Cα1 of the first coil conductor layer 101a of the first coil 101 and the first smallest enclosing circle Col of the first coil conductor layer 102a of the second coil 102 do not overlap each other, and the second smallest enclosing circle Cα2 of the second coil conductor layer 101b of the first coil 101 and the second smallest enclosing circle Cβ2 of the second coil conductor layer 102b of the second coil 102 do not overlap each other, so that cancellation of the magnetic flux of the first coil 101 and the magnetic flux of the second coil 102 is reduced.

At least one set of two adjacent coils among the first to twelfth coils 101 to 112 need only satisfy the above-described configuration. According to an exemplary aspect, all sets of two adjacent coils need only satisfy the above-described configuration.

### First Modification Example

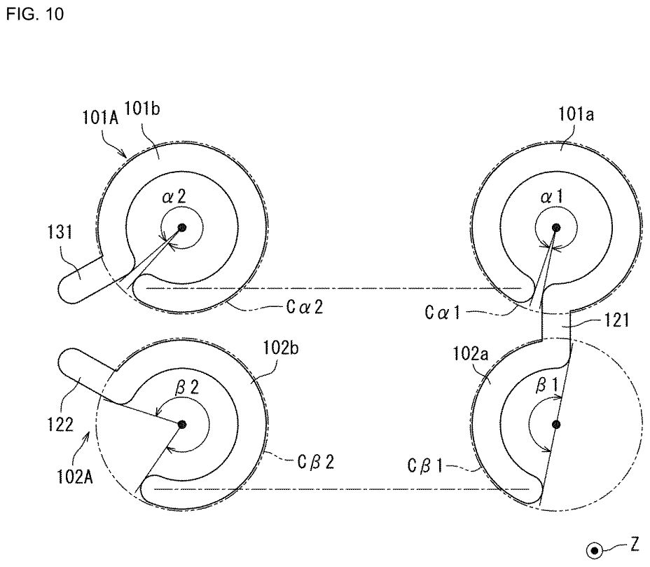

FIG. 10 is an exploded plan view showing a first modification example of a second form of the inductor component. FIG. 10 is a view corresponding to FIG. 6. The first modification example is different from the form shown in FIG. 6 in the configurations of the first coil and the second coil. The different configuration will be described below.

As shown in FIG. 10, when viewed in the first direction Z, the first coil conductor layer 101a of a first coil 101A has an arc shape provided in a range where a first central angle α1 is 180° or more and 355° or less. The first central angle α1 refers to an angle between two tangents when a tangent that is tangent to each of both end portions of the first coil conductor layer 101a is drawn from a center of the first smallest enclosing circle Cα1 enclosing the first coil conductor layer 101a having an arc shape, when viewed in the first direction Z. The arc shape of the first coil conductor layer 101a is longer than the arc shape of the first coil conductor layer 101a shown in FIG. 6. Specifically, the first central angle α1 is, for example, 355°.

When viewed in the first direction Z, the second coil conductor layer 101b of the first coil 101A has an arc shape provided in a range where a second central angle α2 is 180° or more and 355° or less. The second central angle α2 refers to an angle between two tangents when a tangent that is tangent to each of both end portions of the second coil conductor layer 101b is drawn from a center of the second smallest enclosing circle Cα2 enclosing the second coil conductor layer 101b having an arc shape, when viewed in the first direction Z. The arc shape of the second coil conductor layer 101b is longer than the arc shape of the second coil conductor layer 101b shown in FIG. 6. Specifically, the second central angle α2 is, for example, 355°.

When viewed in the first direction Z, the first coil conductor layer 102a of a second coil 102A has an arc shape provided in a range where a first central angle β1 is 180° or more and 355° or less. The first central angle β1 refers to an angle between two tangents when a tangent that is tangent to each of both end portions of the first coil conductor layer 102a is drawn from a center of the first smallest enclosing circle Cβ1 enclosing the first coil conductor layer 102a having an arc shape, when viewed in the first direction Z. The arc shape of the first coil conductor layer 102a is shorter than the arc shape of the first coil conductor layer 102a shown in FIG. 6. Specifically, the first central angle β1 is, for example, 180°.

When viewed in the first direction Z, the second coil conductor layer 102b of the second coil 102A has an arc shape provided in a range where a second central angle β2 is 180° or more and 355° or less. The second central angle β2 refers to an angle between two tangents when a tangent that is tangent to each of both end portions of the second coil conductor layer 102b is drawn from a center of the second smallest enclosing circle Cβ2 enclosing the second coil conductor layer 102b having an arc shape, when viewed in the first direction Z. The arc shape of the second coil conductor layer 102b is shorter than the arc shape of the second coil conductor layer 102b shown in FIG. 6. Specifically, the second central angle β2 is, for example, 287°.

With the above configuration, lengths of the first coil 101A and the second coil 102A can be changed, and the inductance value can be easily changed.

The first connection conductor 121 is connected in the same layer as the first coil conductor layer 101a and the first coil conductor layer 102a. The first extended conductor 131 is connected in the same layer as the second coil conductor layer 101b. The second connection conductor 122 is connected in the same layer as the second coil conductor layer 102b.

### Third Exemplary Aspect

### (Configuration)

As shown in FIG. 3 and FIG. 4, the inductor component 1 includes the first to seventh coils 101 to 107 including at least the first coil 101 and the second coil 102. The first to seventh coils 101 to 107 are disposed on the plane and are connected in series to each other to form the first inductor group 141. The first to seventh coils 101 to 107 respectively have the first coil conductor layers 101a to 107a and the second coil conductor layers 101b to 107b, which are stacked in the first direction Z. In each of the first to seventh coils 101 to 107, the number of all the coil conductor layers included in one coil is smaller than the number of all the coil conductor layers included in the first inductor group 141.

Specifically, in each of the first to seventh coils 101 to 107, the number of all the coil conductor layers included in one coil is two layers, that is, the first and second coil conductor layers. The number of all the coil conductor layers included in the first inductor group 141 is 14 layers, which is obtained by multiplying seven coils by two coil conductor layers.

With the above configuration, the inductor component 1 can be thinned as compared with a case where the plurality of coils are stacked in the first direction in one first inductor group 141.

Similarly, the eight to tenth coils 108 to 110 are disposed on the plane and are connected in series to each other to form the second inductor group 142. The eight to tenth coils 108 to 110 respectively have the first coil conductor layers 108a to 110a and the second coil conductor layers 108b to 110b, which are stacked in the first direction Z. In each of the eight to tenth coils 108 to 110, the number of all the coil conductor layers included in one coil is smaller than the number of all the coil conductor layers included in the second inductor group 142. Specifically, the number of all the coil conductor layers included in one coil is two layers, and the number of all the coil conductor layers included in the second inductor group 142 is (3×2=) six layers.

With the above configuration, the inductor component 1 can be thinned as compared with a case where the plurality of coils are stacked in the first direction in one second inductor group 142.

Similarly, the eleventh and twelfth coils 111 and 112 are disposed on the plane and are connected in series to each other to form the third inductor group 143. The eleventh and twelfth coils 111 and 112 respectively have the first coil conductor layers 111a and 112a and the second coil conductor layers 111b and 112b, which are stacked in the first direction Z. In each of the eleventh and twelfth coils 111 and 112, the number of all the coil conductor layers included in one coil is smaller than the number of all the coil conductor layers included in the third inductor group 143. Specifically, the number of all the coil conductor layers included in one coil is two layers, and the number of all the coil conductor layers included in the third inductor group 143 is (2×2=) four layers.

With the above configuration, the inductor component 1 can be thinned as compared with a case where the plurality of coils are stacked in the first direction in one third inductor group 143.

### First Modification Example

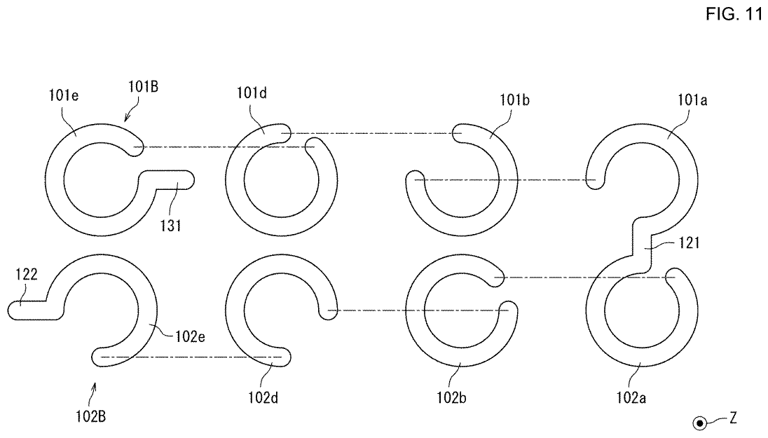

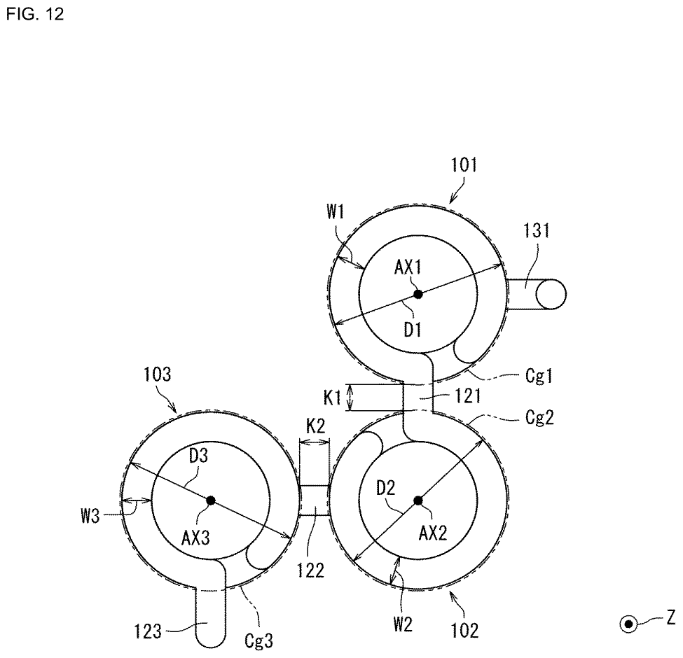

FIG. 11 is an exploded plan view showing a first modification example of a third form of the inductor component. FIG. 11 is a view corresponding to FIG. 6. The first modification example is different from the form shown in FIGS. 4 and 6 in the number of coil conductor layers of each of the first coil and the second coil. The different configuration will be described below.

As shown in FIG. 11, a first coil 101B has the first coil conductor layer 101a, the second coil conductor layer 101b, a third coil conductor layer 101d, and a fourth coil conductor layer 101e. A second coil 102B has the first coil conductor layer 102a, the second coil conductor layer 102b, a third coil conductor layer 102d, and a fourth coil conductor layer 102e. That is, in each of the first and second coils 101B and 102B, the number of all the coil conductor layers included in one coil is four layers, that is, the first to fourth coil conductor layers. In this case, similarly for the third to seventh coils 103 to 107, the number of all the coil conductor layers included in one coil is four layers.

In each of the first to seventh coils 101B, 102B, and 103 to 107, the number of all the coil conductor layers included in one coil is four layers. The number of all the coil conductor layers included in the first inductor group 141 is (7×4=) 28 layers. As described above, in each of the first to seventh coils 101B, 102B, and 103 to 107, the number of all the coil conductor layers included in one coil is smaller than the number of all the coil conductor layers included in the first inductor group 141. With the above configuration, the inductor component 1 can be thinned as compared with a case where the plurality of coils are stacked in the first direction in one first inductor group 141.

In the exemplary aspect, the coils forming the second inductor group 142 and the coils forming the third inductor group 143 may have the same configuration as the coils forming the first inductor group 141.

### Fourth Exemplary Aspect

### (Configuration)

FIG. 12 is a plan view showing a fourth form of the inductor component. FIG. 12 is a view corresponding to FIG. 5. FIG. 12 is different from FIG. 5 in that the third coil is shown. The different configuration will be described below.

As shown in FIG. 12, the third coil 103 is disposed on the same plane as the second coil 102 and is adjacent to the second coil 102. The third coil 103 is wound spirally along a third axis AX3. The third axis AX3 and the second axis AX2 are orthogonal to the plane and are disposed parallel to each other. That is, the third axis AX3 and the second axis AX2 are disposed parallel to the first direction Z.

The second connection conductor 122 connects the end portion of the second coil 102 and the end portion of the third coil 103. When viewed in the first direction Z, the second connection conductor 122 is located between a third smallest enclosing circle Cg3, which is a smallest circle enclosing the third coil 103, and the second smallest enclosing circle Cg2, which is the smallest circle enclosing the second coil 102. In FIG. 5, the third smallest enclosing circle Cg3 is shown by a two-point chain line, and for convenience, the third smallest enclosing circle Cg3 is shown to be spaced apart from the third coil 103.

When viewed in the first direction Z, a second shortest distance K2 between the third coil 103 and the second coil 102 is equal to or greater than a largest wiring width among a third wiring width W3 of the third coil 103 and the second wiring width W2 of the second coil 102, and is equal to or less than an average value of a third diameter D3 of the third smallest enclosing circle Cg3 and the second diameter D2 of the second smallest enclosing circle Cg2. The second shortest distance K2 is a shortest distance between an end portion of the third coil 103 and the end portion of the second coil 102. The third wiring width W3 is an average width of a wiring of the third coil 103. The second wiring width W2 is an average width of a wiring of the second coil 102. In the present exemplary embodiment, the third wiring width W3 and the second wiring width W2 are the same, and the third diameter D3 and the second diameter D2 are the same. The third wiring width W3 and the second wiring width W2 may be different from each other, and the third diameter D3 and the second diameter D2 may be different from each other.

With the above configuration, since the third coil 103 and the second coil 102 are provided, an inductance value is improved. In this case, since the third coil 103 and the second coil 102 are disposed on the same plane in the element body 10 and are adjacent to each other, and the third axis AX3 of the third coil 103 and the second axis AX2 of the second coil 102 are orthogonal to the plane and are disposed parallel to each other, the inductor component 1 can be thinned.

In addition, since the third coil 103 and the second coil 102 are disposed on the same plane in the element body 10 and are adjacent to each other, the inductance value is improved while thinning the inductor component 1 without reducing a wiring thickness of the coil as compared with a case where the first to third coils 101 to 103 are stacked in the first direction Z. As a result, an increase in a resistance value of the coil according to the thickness of the wiring is suppressed, and an increase in power loss is suppressed. In addition, since the third coil 103 and the second coil 102 are disposed on the same plane in the element body 10 and are adjacent to each other, the inductance value is improved while thinning the inductor component 1 without reducing a thickness of the magnetic layer as compared with a case where the first to third coils 101 to 103 are stacked in the first direction Z. As a result, a decrease in the inductance value due to magnetism saturation according to the thickness of the magnetic layer is suppressed, and a deterioration in the DC superposition performance is suppressed. In this way, even in a case where an attempt is made to obtain a high inductance value while thinning the inductor component 1, a deterioration in the performance of the inductor component 1 is suppressed.

Further, when viewed in the first direction Z, the second shortest distance K2 between the third coil 103 and the second coil 102 is equal to or greater than the largest wiring width among the third wiring width W3 of the third coil 103 and the second wiring width W2 of the second coil 102, so that a possibility that the third coil 103 and the second coil 102 are electrically connected at positions other than the end portions thereof is reduced.

In addition, when viewed in the first direction Z, the second shortest distance K2 between the third coil 103 and the second coil 102 is equal to or less than the average value of the third diameter D3 of the third smallest enclosing circle Cg3, which is the smallest circle enclosing the third coil 103, and the second diameter D2 of the second smallest enclosing circle Cg2, which is the smallest circle enclosing the second coil 102, so that miniaturization can be achieved in a plane direction without requiring a space between the third coil 103 and the second coil 102 so as to place another coil adjacent.

Although the above configuration is satisfied in the adjacent first to third coils 101 to 103, at least one set of three adjacent coils among the plurality of coils need only satisfy the above configuration. According to an exemplary aspect, all sets of three adjacent coils need only satisfy the above-described configuration.

### Fifth Exemplary Aspect

### (Configuration)

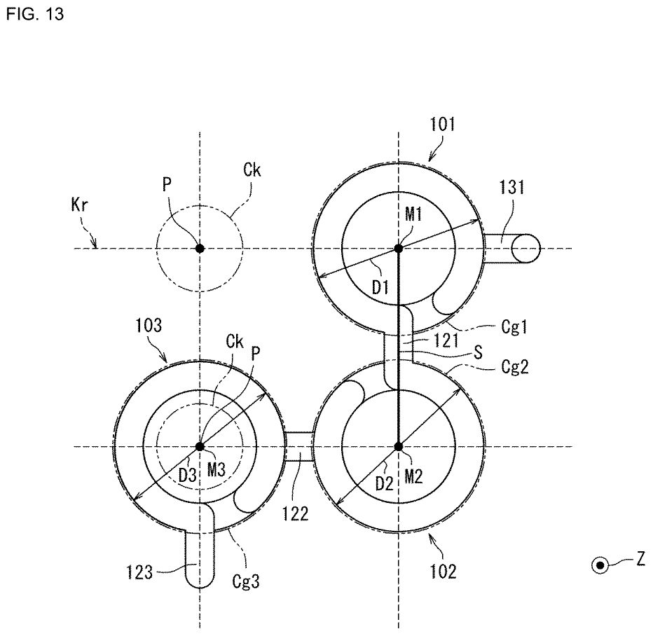

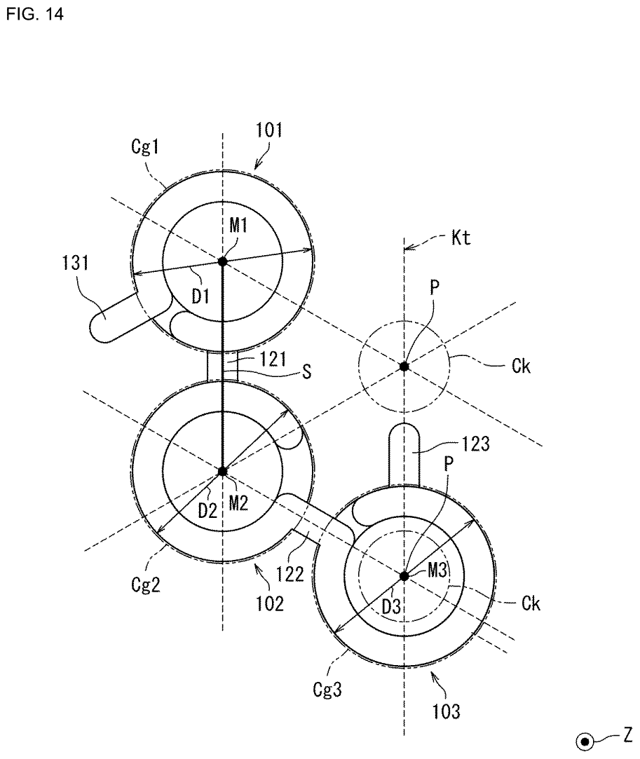

FIG. 13 is a plan view showing a fifth form of the inductor component. FIG. 13 is a view corresponding to FIG. 12. FIG. 13 is different from FIG. 12 in that the centers of the smallest enclosing circles of the first to third coils are shown. The different configuration will be described below.

As shown in FIG. 13, the fifth form is based on the fourth form shown in FIG. 12. When viewed in the first direction Z, imaginary square lattice points are defined in which a line segment S connecting a first center M1 of the first smallest enclosing circle Cg1, which is the smallest circle enclosing the first coil 101, and a second center M2 of the second smallest enclosing circle Cg2, which is the smallest circle enclosing the second coil 102, is used as one side. An imaginary square lattice Kr is represented by a dotted line, and lattice points P of the square lattice are represented by black circles. FIG. 13 partially shows the square lattice Kr and the lattice points P.

A third center M3 of the third smallest enclosing circle Cg3, which is the smallest circle enclosing the third coil 103, is located inside an imaginary circle Ck centered on the square lattice point P. A diameter of the imaginary circle Ck is half of an average value of the first diameter D1 of the first smallest enclosing circle Cg1, which is the smallest circle enclosing the first coil 101, the second diameter D2 of the second smallest enclosing circle Cg2, which is the smallest circle enclosing the second coil 102, and the third diameter D3 of the third smallest enclosing circle Cg3, which is the smallest circle enclosing the third coil 103.

With the above configuration, the first coil 101, the second coil 102, and the third coil 103 can be efficiently disposed within a limited area, and the inductor component can be miniaturized. According to an exemplary aspect, when viewed in the first direction Z, an angle formed by a straight line connecting the first center M1 and the second center M2 and a straight line connecting the second center M2 and the third center M3 is in a range of 85° to 95°.

Although the above configuration is satisfied in the adjacent first to third coils 101 to 103, at least one set of three adjacent coils among the plurality of coils need only satisfy the above configuration. According to an exemplary aspect, all sets of three adjacent coils need only satisfy the above-described configuration.

### First Modification Example

FIG. 14 is a plan view showing a first modification example of the fifth form of the inductor component. FIG. 14 is a view corresponding to FIG. 13. The first modification example is different from the form shown in FIG. 13 in the position of the third coil. The different configuration will be described below.

As shown in FIG. 14, when viewed in the first direction Z, imaginary equilateral triangle lattice points are defined in which a line segment S connecting a first center M1 of the first smallest enclosing circle Cg1, which is the smallest circle enclosing the first coil 101, and a second center M2 of the second smallest enclosing circle Cg2, which is the smallest circle enclosing the second coil 102, is used as one side. An imaginary equilateral triangle lattice Kt is represented by a dotted line, and lattice points P of the equilateral triangle lattice are represented by black circles. In FIG. 14, the equilateral triangle lattice Kt and the lattice points P are partially shown.

A third center M3 of the third smallest enclosing circle Cg3, which is the smallest circle enclosing the third coil 103, is located inside an imaginary circle Ck centered on the equilateral triangle lattice point P. A diameter of the imaginary circle Ck is half of an average value of the first diameter D1 of the first smallest enclosing circle Cg1, which is the smallest circle enclosing the first coil 101, the second diameter D2 of the second smallest enclosing circle Cg2, which is the smallest circle enclosing the second coil 102, and the third diameter D3 of the third smallest enclosing circle Cg3, which is the smallest circle enclosing the third coil 103. The third center M3 is present at such a position that an angle formed by the straight line connecting the first center M1 and the second center M2 and the straight line connecting the second center M2 and the third center M3 is an obtuse angle.

With the above configuration, the first coil 101, the second coil 102, and the third coil 103 is efficiently disposed within a limited area, and the inductor component can be miniaturized. According to an exemplary aspect, when viewed in the first direction Z, an angle formed by a straight line connecting the first center M1 and the second center M2 and a straight line connecting the second center M2 and the third center M3 is in a range of 115° to 125°.

Although the above configuration is satisfied in the adjacent first to third coils 101 to 103, at least one set of three adjacent coils among the plurality of coils need only satisfy the above configuration. According to an exemplary aspect, all sets of three adjacent coils need only satisfy the above-described configuration.

### Second Modification Example

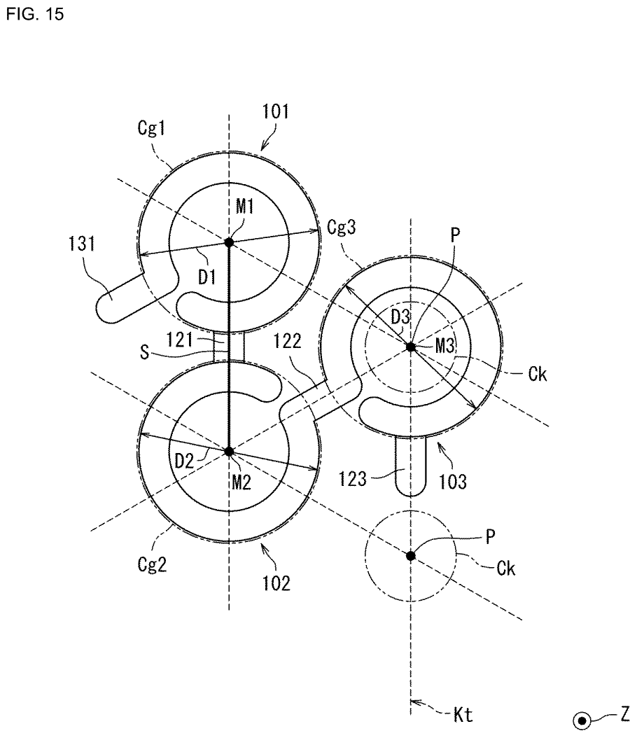

FIG. 15 is a plan view showing a second modification example of the fifth form of the inductor component. FIG. 15 is a view corresponding to FIG. 13. The second modification example is different from the form shown in FIG. 13 in the position of the third coil. The different configuration will be described below.

As shown in FIG. 15, when viewed in the first direction Z, imaginary equilateral triangle lattice points are defined in which a line segment S connecting a first center M1 of the first smallest enclosing circle Cg1, which is the smallest circle enclosing the first coil 101, and a second center M2 of the second smallest enclosing circle Cg2, which is the smallest circle enclosing the second coil 102, is used as one side. An imaginary equilateral triangle lattice Kt is represented by a dotted line, and lattice points P of the equilateral triangle lattice are represented by black circles. In FIG. 15, the equilateral triangle lattice Kt and the lattice points P are partially shown.

A third center M3 of the third smallest enclosing circle Cg3, which is the smallest circle enclosing the third coil 103, is located inside an imaginary circle Ck centered on the equilateral triangle lattice point P. A diameter of the imaginary circle Ck is half of an average value of the first diameter D1 of the first smallest enclosing circle Cg1, which is the smallest circle enclosing the first coil 101, the second diameter D2 of the second smallest enclosing circle Cg2, which is the smallest circle enclosing the second coil 102, and the third diameter D3 of the third smallest enclosing circle Cg3, which is the smallest circle enclosing the third coil 103. The third center M3 is present at such a position that an angle formed by the straight line connecting the first center M1 and the second center M2 and the straight line connecting the second center M2 and the third center M3 is an acute angle.

With the above configuration, the first coil 101, the second coil 102, and the third coil 103 is efficiently disposed within a limited area, and the inductor component can be miniaturized. According to an exemplary aspect, when viewed in the first direction Z, an angle formed by a straight line connecting the first center M1 and the second center M2 and a straight line connecting the second center M2 and the third center M3 is in a range of 55° to 65°.

Although the above configuration is satisfied in the adjacent first to third coils 101 to 103, at least one set of three adjacent coils among the plurality of coils need only satisfy the above configuration. According to an exemplary aspect, all sets of three adjacent coils need only satisfy the above-described configuration.

### Sixth Exemplary Aspect

### (Configuration)

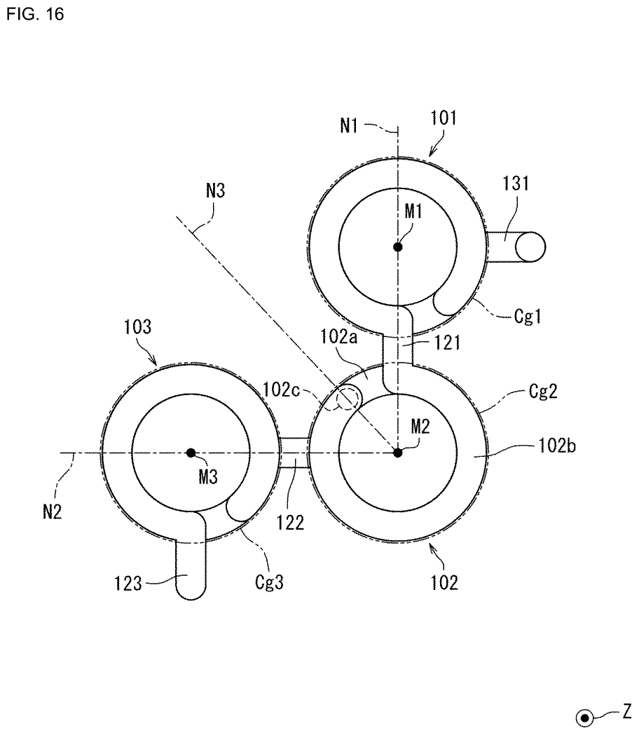

FIG. 16 is a plan view showing a sixth form of the inductor component. FIG. 16 is a view corresponding to FIG. 13. FIG. 16 is different from FIG. 13 in that the via conductor of the second coil is shown. The different configuration will be described below.

As shown in FIG. 16, the sixth form is based on the fifth form shown in FIG. 13. That is, as shown in FIG. 13, a third center M3 of the third smallest enclosing circle Cg3, which is the smallest circle enclosing the third coil 103, is located inside an imaginary circle Ck centered on the square lattice point P.

The second coil 102 has the first coil conductor layer 102a, the second coil conductor layer 102b stacked in the first direction Z on the first coil conductor layer 102a, and the via conductor 102c that extends in the first direction Z and connects the first coil conductor layer 102a and the second coil conductor layer 102b.

When viewed in the first direction Z, a straight line connecting the first center M1 of the first smallest enclosing circle Cg1, which is the smallest circle enclosing the first coil 101, and the second center M2 of the second smallest enclosing circle Cg2, which is the smallest circle enclosing the second coil 102, is defined as a first straight line N1. A straight line connecting the third center M3 of the third smallest enclosing circle Cg3, which is the smallest circle enclosing the third coil 103, and the second center M2 of the second smallest enclosing circle Cg2, which is the smallest circle enclosing the second coil 102, is defined as a second straight line N2. A straight line that bisects an angle formed by the first straight line N1 and the second straight line N2 is defined as a third straight line N3. The via conductor 102c of the second coil 102 overlaps the third straight line N3.

With the above configuration, the first coil 101, the second coil 102, and the third coil 103 is efficiently disposed within a limited area, the inductor component 1 can be miniaturized, and the inductance value is improved. In addition, since the first coil conductor layer 102a and the second coil conductor layer 102b of the second coil 102 can be disposed in a line-symmetrical manner with respect to the third straight line N3, warping due to thermal stress or the like is suppressed. According to an exemplary aspect, when viewed in the first direction Z, a center of the via conductor 102c of the second coil 102 overlaps the third straight line N3.

Although the above configuration is satisfied in the adjacent first to third coils 101 to 103, at least one set of three adjacent coils among the plurality of coils need only satisfy the above configuration. According to an exemplary aspect, all sets of three adjacent coils need only satisfy the above-described configuration. In addition, the third center M3 of the third smallest enclosing circle Cg3, which is the smallest circle enclosing the third coil 103, does not have to be located inside an imaginary circle Ck centered on the square lattice point P.

### First Modification Example

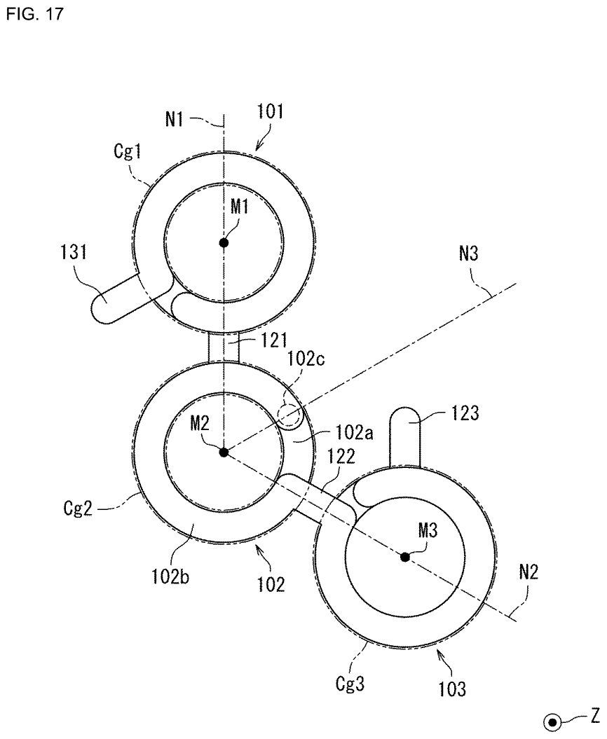

FIG. 17 is a plan view showing a first modification example of the sixth form of the inductor component. The first modification example is different from the form shown in FIG. 16 in the position of the third coil.

As shown in FIG. 17, in the first modification example, a position of the third coil is the same as that of the first modification example of the fifth form shown in FIG. 14. That is, as shown in FIG. 14, a third center M3 of the third smallest enclosing circle Cg3, which is the smallest circle enclosing the third coil 103, is located inside an imaginary circle Ck centered on the equilateral triangle lattice point P.

When viewed in the first direction Z, a straight line connecting the first center M1 of the first smallest enclosing circle Cg1, which is the smallest circle enclosing the first coil 101, and the second center M2 of the second smallest enclosing circle Cg2, which is the smallest circle enclosing the second coil 102, is defined as a first straight line N1. A straight line connecting the third center M3 of the third smallest enclosing circle Cg3, which is the smallest circle enclosing the third coil 103, and the second center M2 of the second smallest enclosing circle Cg2, which is the smallest circle enclosing the second coil 102, is defined as a second straight line N2. A straight line that bisects an angle formed by the first straight line N1 and the second straight line N2 is defined as a third straight line N3. The via conductor 102c of the second coil 102 overlaps the third straight line N3.

With the above configuration, the first coil 101, the second coil 102, and the third coil 103 is efficiently disposed within a limited area, the inductor component 1 can be miniaturized, and the inductance value is improved. In addition, since the first coil conductor layer 102a and the second coil conductor layer 102b of the second coil 102 can be disposed in a line-symmetrical manner with respect to the third straight line N3, warping due to thermal stress or the like is suppressed. According to an exemplary aspect, when viewed in the first direction Z, a center of the via conductor 102c of the second coil 102 overlaps the third straight line N3.

Although the above configuration is satisfied in the adjacent first to third coils 101 to 103, at least one set of three adjacent coils among the plurality of coils need only satisfy the above configuration. According to an exemplary aspect, all sets of three adjacent coils need only satisfy the above-described configuration. In addition, the third center M3 of the third smallest enclosing circle Cg3, which is the smallest circle enclosing the third coil 103, does not have to be located inside an imaginary circle Ck centered on the equilateral triangle lattice point P.

### Second Modification Example

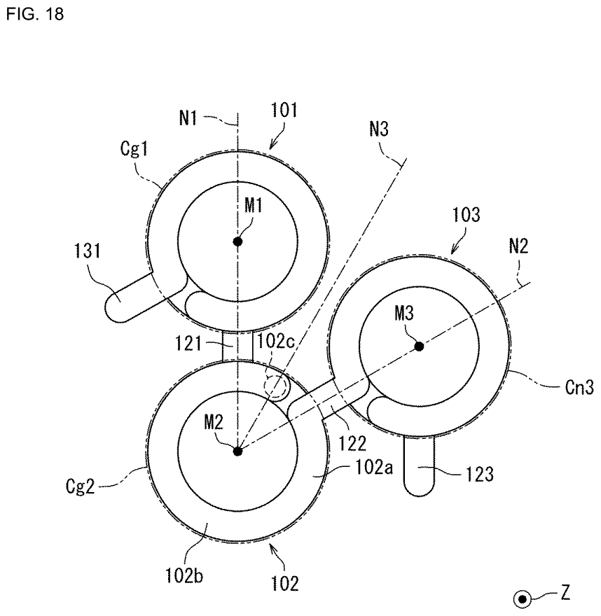

FIG. 18 is a plan view showing a second modification example of the sixth form of the inductor component. The second modification example is different from the form shown in FIG. 16 in the position of the third coil.

As shown in FIG. 18, in the second modification example, a position of the third coil is the same as that of the second modification example of the fifth form shown in FIG. 15. That is, as shown in FIG. 15, a third center M3 of the third smallest enclosing circle Cg3, which is the smallest circle enclosing the third coil 103, is located inside an imaginary circle Ck centered on the equilateral triangle lattice point P.

When viewed in the first direction Z, a straight line connecting the first center M1 of the first smallest enclosing circle Cg1, which is the smallest circle enclosing the first coil 101, and the second center M2 of the second smallest enclosing circle Cg2, which is the smallest circle enclosing the second coil 102, is defined as a first straight line N1. A straight line connecting the third center M3 of the third smallest enclosing circle Cg3, which is the smallest circle enclosing the third coil 103, and the second center M2 of the second smallest enclosing circle Cg2, which is the smallest circle enclosing the second coil 102, is defined as a second straight line N2. A straight line that bisects an angle formed by the first straight line N1 and the second straight line N2 is defined as a third straight line N3. The via conductor 102c of the second coil 102 overlaps the third straight line N3.

With the above configuration, the first coil 101, the second coil 102, and the third coil 103 is efficiently disposed within a limited area, the inductor component 1 can be miniaturized, and the inductance value is improved. In addition, since the first coil conductor layer 102a and the second coil conductor layer 102b of the second coil 102 can be disposed in a line-symmetrical manner with respect to the third straight line N3, warping due to thermal stress or the like is suppressed. According to an exemplary aspect, when viewed in the first direction Z, a center of the via conductor 102c of the second coil 102 overlaps the third straight line N3.

Although the above configuration is satisfied in the adjacent first to third coils 101 to 103, at least one set of three adjacent coils among the plurality of coils need only satisfy the above configuration. According to an exemplary aspect, all sets of three adjacent coils need only satisfy the above-described configuration. In addition, the third center M3 of the third smallest enclosing circle Cg3, which is the smallest circle enclosing the third coil 103, does not have to be located inside an imaginary circle Ck centered on the equilateral triangle lattice point P.

### Seventh Exemplary Aspect

### (Configuration)

A seventh form of the inductor component will be described with reference to FIGS. 3 and 12. The inductor component 1 includes the first to seventh coils 101 to 107 including at least the first coil 101 and the second coil 102. The first to seventh coils 101 to 107 are disposed on the plane and are connected in series to each other to form the first inductor group 141. When viewed in the first direction Z, an average value of the diameters of the smallest enclosing circles enclosing the coils 101 to 107 is defined as a first reference value, and an average value of the wiring widths of the coils 101 to 107 is defined as a second reference value.

Specifically, the first reference value is an average value of the first diameter D1 of the first smallest enclosing circle Cg1 which is the smallest circle enclosing the first coil 101, the second diameter D2 of the second smallest enclosing circle Cg2 which is the smallest circle enclosing the second coil 102, the third diameter D3 of the third smallest enclosing circle Cg3 which is the smallest circle enclosing the third coil 103, the fourth diameter of the fourth smallest enclosing circle which is the smallest circle enclosing the fourth coil 104, the fifth diameter of the fifth smallest enclosing circle which is the smallest circle enclosing the fifth coil 105, the sixth diameter of the sixth smallest enclosing circle which is the smallest circle enclosing the sixth coil 106, and the seventh diameter of the seventh smallest enclosing circle which is the smallest circle enclosing the seventh coil 107. The first to seventh diameters are substantially equal to each other and substantially equal to the first reference value.

The second reference value is an average value of the first wiring width W1 of the first coil 101, the second wiring width W2 of the second coil 102, the third wiring width W3 of the third coil 103, the fourth wiring width of the fourth coil 104, the fifth wiring width of the fifth coil 105, the sixth wiring width of the sixth coil 106, and the seventh wiring width of the seventh coil 107. The first to seventh wiring widths are substantially equal to each other and substantially equal to the second reference value.

A first reference coil that has a smallest enclosing circle of which a diameter is 0.5 times the first reference value and which has a wiring width equal to the second reference value is defined. A second reference coil that has a smallest enclosing circle of which a diameter is 2 times the first reference value and which has a wiring width equal to the second reference value is defined. The inductance value per unit area of each of the coils 101 to 107 is larger than the inductance value per unit area of the first reference coil and is larger than the inductance value per unit area of the second reference coil.

The inductance value per unit area of each of the coils 101 to 107 is a value obtained by dividing the inductance value of each of the coils 101 to 107 by an area of the smallest enclosing circle of each of the coils 101 to 107. The inductance value per unit area of the first reference coil is a value obtained by dividing the inductance value of the first reference coil by an area of the smallest enclosing circle of the first reference coil. The inductance value per unit area of the second reference coil is a value obtained by dividing the inductance value of the second reference coil by an area of the smallest enclosing circle of the second reference coil. Hereinafter, the inductance value per unit area of the coil will also be referred to as an inductance value density.

With the above configuration, the inductance value per unit area of each of the coils 101 to 107 can be increased, and the miniaturization of the inductor component 1 and the improvement of the inductance value is satisfied. The second and third inductor groups 142 and 143 may have the same configuration as the first inductor group 141.

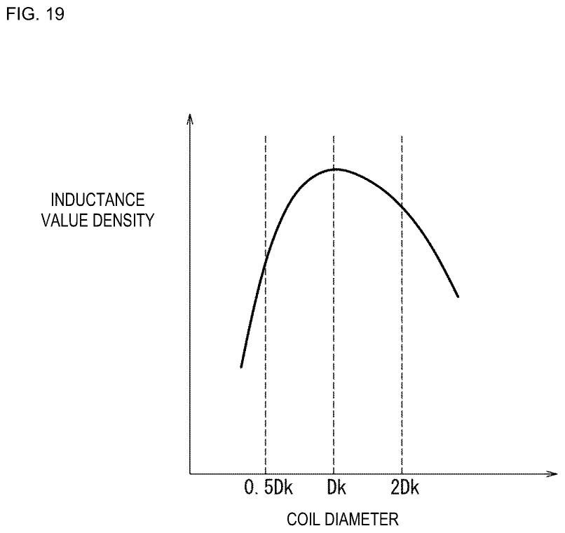

Hereinafter, the configurations of the second and third inductor groups 142 and 143 will be described in detail. FIG. 19 is a graph showing a relationship between a coil diameter and an inductance value density. The coil diameter is shown on a horizontal axis, and the inductance value density is shown on a vertical axis. The coil diameter is a diameter of a smallest enclosing circle of the coil. The inductance value density is an inductance value per unit area of the coil.

As shown in FIG. 19, since the first to seventh diameters are substantially equal to the first reference value, in a case where the first reference value is denoted by Dk, the inductance value density at the diameter (first reference value Dk) of each coil is larger than the inductance value density in the first reference coil of which a diameter is 0.5 times the first reference value Dk, and is larger than the inductance value density in the second reference coil of which a diameter is 2 times the first reference value Dk. That is, the diameter (first reference value Dk) of each coil passes through the vicinity including a peak position of the graph shown in FIG. 19. Therefore, since the inductance value per unit area of each of the coils 101 to 107 is large, the miniaturization of the inductor component 1 and the improvement of the inductance value is achieved.

As described above, as a result of the intensive studies, the present inventor of the present application has found for the first time that the inductance value per unit area occupied by the coil exhibits an upwardly convex curve as shown in FIG. 19. As a result, the present inventor has paid attention that the coil diameter passing through the peak position of this curve has the highest acquisition efficiency of the inductance value. Then, by constructing an inductor component using a plurality of coils having the coil diameter, an inductor component that can achieve both the miniaturization and the improvement of the inductance value was realized.

Here, in a case where the coil diameter is increased beyond the peak position shown in FIG. 19, the inductance value itself is increased as the wiring length of the coil is extended, but the coil may be enlarged. That is, it is possible to obtain a desired inductance value in a small size by connecting in series a plurality of coils having diameters that provide high acquisition efficiency of the inductance value to obtain an inductance value. In this way, the coil diameter at which the inductance value density is maximized is determined, the coil having the coil diameter is used as a unit, and the unit is electrically connected and laid out on a plane, so that a desired inductance value is obtained. The peak value of the graph shown in FIG. 19 can be changed by changing the magnetic permeability of the material surrounding the coil and the wiring width of the coil.

### Example

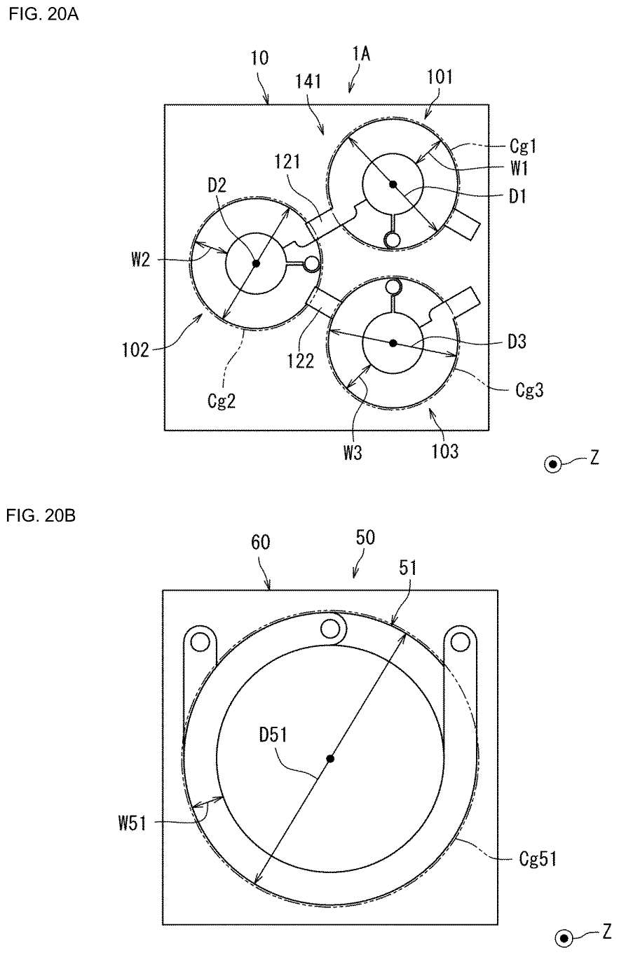

Hereinafter, an example will be described. FIG. 20A is a plan view showing an example of the seventh form of the inductor component. As shown in FIG. 20A, an inductor component 1A includes the first to third coils 101 to 103. The first to third coils 101 to 103 are disposed on the plane and are connected in series to each other to form the first inductor group 141. The disposition of the first to third coils 101 to 103 is the same as the disposition shown in FIG. 15.

When viewed in the first direction Z, an average value of the diameters D1 to D3 of the smallest enclosing circles Cg1 to Cg3 enclosing the coils 101 to 103 is defined as a first reference value, and an average value of the wiring widths W1 to W3 of the coils 101 to 103 is defined as a second reference value. Specifically, the first reference value is an average value of the first diameter D1 of the first smallest enclosing circle Cg1, which is the smallest circle enclosing the first coil 101, the second diameter D2 of the second smallest enclosing circle Cg2, which is the smallest circle enclosing the second coil 102, and the third diameter D3 of the third smallest enclosing circle Cg3, which is the smallest circle enclosing the third coil 103. The second reference value is an average value of the first wiring width W1 of the first coil 101, the second wiring width W2 of the second coil 102, and the third wiring width W3 of the third coil 103. The first to third diameters D1 to D3 are equal to each other and equal to the first reference value. The first to third wiring widths W1 to W3 are equal to each other and equal to the second reference value.

A first reference coil that has a smallest enclosing circle of which a diameter is 0.5 times the first reference value and which has a wiring width equal to the second reference value is defined. A second reference coil that has a smallest enclosing circle of which a diameter is 2 times the first reference value and which has a wiring width equal to the second reference value is defined. The inductance value density of each of the coils 101 to 103 is larger than the inductance value density of the first reference coil and is larger than the inductance value density of the second reference coil.

With the above configuration, the inductance value density of each of the coils 101 to 103 is increased, and the miniaturization of the inductor component 1A and the improvement of the inductance value is satisfied.

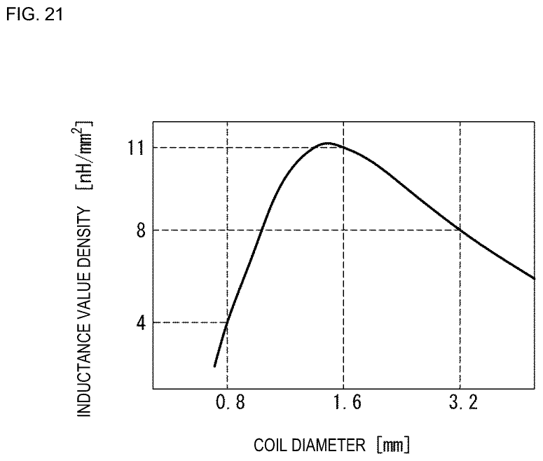

Specifically, the first reference value was set to 1.6 mm and the second reference value was set to 0.5 mm. A specific permeability of the element body 10 was set to 30. FIG. 21 shows a relationship between the coil diameter [mm] and the inductance value density [nH/mm] in this case. As shown in FIG. 21, the inductance value density had a peak value in the vicinity of the coil diameter of 1.6 mm. An inductance value of one coil having the coil diameter of 1.6 mm was 0.07 μH. Since the inductor component 1A of the present example has three coils, the inductance value of the inductor component 1A was (0.07 μH×3=) 0.21 μH. The size of the inductor component 1A, that is, the size of the element body 10 was (4.7 mm×4.7 mm=) 22 mm2.

FIG. 20B is a plan view showing a comparative example of the inductor component. As shown in FIG. 20B, an inductor component 50 includes a first coil 51. When viewed in the first direction Z, a diameter D51 of a smallest enclosing circle Cg51 enclosing the first coil 51 is equal to 2 times the first reference value, and a wiring width W51 of the first coil 51 is equal to the second reference value. That is, the first coil 51 is the second reference coil. Specifically, the diameter D51 of the smallest enclosing circle Cg51 enclosing the first coil 51 was (1.6 mm×2=) 3.2 mm. The inductance value of the first coil 51 was 0.2 μH. The size of the inductor component 50, that is, a size of an element body 60 was (5.0 mm×5.0 mm=) 25 mm2. Therefore, the inductor component 50 of the comparative example was larger than the inductor component 1A of the present example. In addition, as shown in FIG. 21, in a case where the coil diameter is 3.2 mm, the inductance value density is low.

Hereinafter, still another form of the present disclosure will be described with reference to the accompanying drawings. In the following description, components corresponding to the components of the above-described forms are denoted by the same names as those of the above-described forms. In addition, each component will be mainly described in terms of differences from the corresponding components of the above-described forms, and the same configuration will be omitted from the description as appropriate.

### Eighth Exemplary Aspect

The inductor component according to the eighth form is different from the above-described forms in that the inductor component includes two coils connected in parallel to each other.

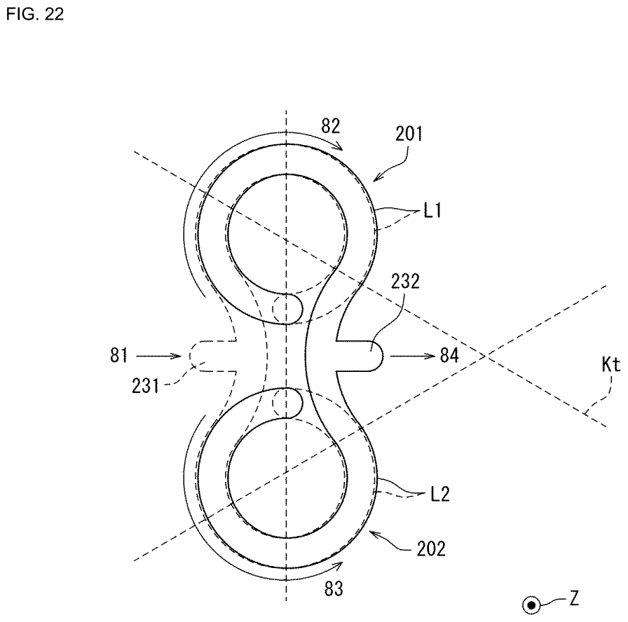

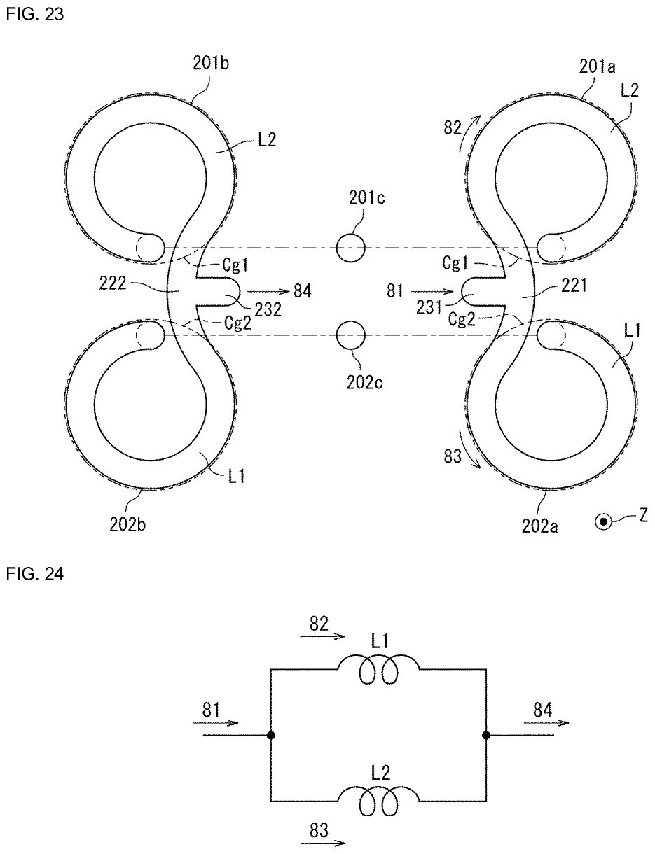

FIG. 22 is a plan view showing a plurality of coils of the inductor component. FIG. 23 is an exploded plan view of FIG. 22. FIGS. 22 and 23 are views corresponding to, for example, FIGS. 5 and 6. FIG. 24 is an equivalent circuit diagram of the plurality of coils shown in FIG. 22. Arrows 81 to 84 in FIGS. 22 to 24 illustrate a direction of the current.

As shown in FIGS. 22 and 23, the inductor component according to the present form includes a first coil 201 and a second coil 202 that are disposed on the same plane in the element body, a first connection conductor 221 and a second connection conductor 222 that are disposed in the element body, and a first extended conductor 231 and a second extended conductor 232 that are disposed in the element body. Axes of the first coil 201 and the second coil 202 are orthogonal to the plane and are disposed parallel to each other.

The first coil 201 and the second coil 202 are connected in parallel to each other by the first connection conductor 221 and the second connection conductor 222.

Hereinafter, detailed configurations of the coils 201 and 202 will be described. The first coil 201 has a first coil conductor layer 201a, a second coil conductor layer 201b stacked in the first direction Z on the first coil conductor layer 201a, and a via conductor 201c. The first coil conductor layer 201a and the second coil conductor layer 201b are electrically connected to each other with the via conductor 201c interposed therebetween. Similarly, the second coil 202 has a first coil conductor layer 202a, a second coil conductor layer 202b stacked in the first direction Z on the first coil conductor layer 202a, and a via conductor 202c. The first coil conductor layer 202a and the second coil conductor layer 202b are electrically connected to each other with the via conductor 202c interposed therebetween.

The first connection conductor 221 connects an end portion of the first coil conductor layer 201a and an end portion of the first coil conductor layer 202a. The second connection conductor 222 connects an end portion of the second coil conductor layer 201b and an end portion of the second coil conductor layer 202b.

In the example shown in FIG. 23, the first coil conductor layers 201a and 202a and the first connection conductor 221 are disposed in the same layer (hereinafter, referred to as a “lower wiring layer”). Similarly, the second coil conductor layers 201b and 202b and the second connection conductor 222 are disposed in the same layer (hereinafter, referred to as an “upper wiring layer”). That is, the inductor component has a structure in which a first conductive pattern including the first coil conductor layers 201a and 202a and the first connection conductor 221 and a second conductive pattern including the second coil conductor layers 201b and 202b and the second connection conductor 222 are stacked in the first direction Z. The first conductive pattern and the second conductive pattern may have a shape in which winding directions of the first coil 201 and the second coil 202 as viewed in the first direction Z are opposite to each other.

The first extended conductor 231 is disposed in, for example, the lower wiring layer and is connected to the first connection conductor 221. The second extended conductor 232 is disposed in, for example, the upper wiring layer and is connected to the second connection conductor 222.

As shown in FIG. 24, the inductor component according to the present form has an inductor portion L1 and an inductor portion L2 that are connected in parallel to each other. The inductor portion L1 is composed of the first coil 201, and the inductor portion L2 is composed of the second coil 202. As shown by arrows 81 to 84 in FIGS. 22 to 24, the current from the first extended conductor 231 flows to the second extended conductor 232 through the first coil 201 (inductor portion L1) and the second coil 202 (inductor portion L2) connected in parallel to each other. In this example, one coil 201 or 202 as a whole forms one inductor portion L1 or L2, but one coil may be divided into a plurality of inductor portions, as described below.

With the above configuration, the inductor component includes a plurality of coils 201 and 202 (two coils here) connected in parallel to each other, so that the inductor component can cope with a larger current. In addition, the inductance value can be adjusted to a desired value by using the parallel connection of the coils.

When viewed in the first direction Z, the winding directions of the two adjacent coils 201 and 202 may be opposite to each other. As a result, magnetic fluxes generated from the two coils 201 and 202 are excited in a direction in which the magnetic fluxes are reinforced by each other, and thus a larger inductance can be realized in a limited formation region.

### First Modification Example

The inductor component according to a first modification example includes a first coil to a third coil. The first modification example is different from the examples shown in FIGS. 22 to 24 in that the third coil is connected in parallel to a part of the first coil and a part of the second coil.

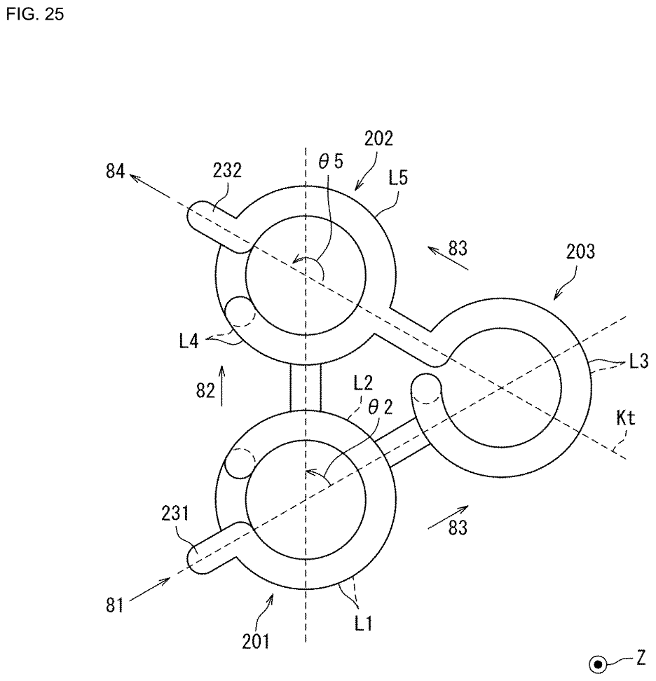

FIG. 25 is a plan view showing a first modification example of the plurality of coils in the inductor component according to the eighth embodiment. FIG. 26 is an exploded plan view of FIG. 25. FIG. 27 is an equivalent circuit diagram of the plurality of coils shown in FIG. 25. Arrows 81 to 84 in FIGS. 25 to 27 illustrate a direction of the current.

As shown in FIGS. 25 and 26, the inductor component according to the present modification example includes a first coil 201 to a third coil 203 that are disposed on the same plane in the element body, a first connection conductor 221 to a third connection conductor 223 that are disposed in the element body, and a first extended conductor 231 and a second extended conductor 232 that are disposed in the element body. Axes of the first coil 201 to the third coil 203 are orthogonal to the plane and are disposed parallel to each other.

The first coil 201 to the third coil 203 have first coil conductor layers 201a to 203a, second coil conductor layers 201b to 203b, and via conductors 201c to 203c, as in the examples shown in FIGS. 22 and 23.

The first connection conductor 221 connects an end portion of the first coil 201 and an end portion of the second coil 202. In this example, the first connection conductor 221 connects an end portion of the first coil conductor layer 201a and an end portion of the first coil conductor layer 202a. The second connection conductor 222 and the third connection conductor 223 connect both end portions of the third coil 203 to a part of the first coil 201 and a part of the second coil 202, respectively. In this example, the second connection conductor 222 connects an end portion of the first coil conductor layer 203a of the third coil 203 and a connection point 222v located between both end portions of the first coil conductor layer 201a. The third connection conductor 223 connects an end portion of the second coil conductor layer 203b of the third coil 203 and a connection point 223v located between both end portions of the second coil conductor layer 202b.

The first coil 201 to the third coil 203 may be disposed such that the centers of the smallest circles thereof form imaginary equilateral triangle lattice points. When viewed in the first direction Z, the diameters of the smallest enclosing circles Cg1 to Cg3 enclosing the first coil 201 to the third coil 203 may be equal to each other. Each of the first connection conductor to the third connection conductor 221 to 223 may extend from an end portion of one coil conductor layer to a part of the other coil conductor layer along any straight line in the equilateral triangle lattice Kt.

The first extended conductor 231 is connected to the end portion of the second coil conductor layer 201b in the first coil 201. The second extended conductor 232 is connected to the end portion of the second coil conductor layer 202b in the second coil 202.

As shown in FIGS. 26 and 27, the first coil 201 is divided into an inductor portion L1 and an inductor portion L2 by the second connection conductor 222. The second coil 202 is divided into an inductor portion L4 and an inductor portion L5 by the third connection conductor 223. The third coil 203 forms an inductor portion L3.

The inductor portion L2, which is a part of the first coil 201, and the inductor portion L4, which is a part of the second coil 202, are connected in series by the first connection conductor 221. The inductor portion L3, which is the third coil 203, is connected in parallel to the inductor portions L1 and L2 by the second connection conductor 222 and the third connection conductor 223.

A detailed configuration of each inductor portion will be described. The inductor portion L1 includes the entire second coil conductor layer 201b and a portion of the first coil conductor layer 201a located from a portion connected to the via conductor 201c to the connection point 222v with the second connection conductor 222. A winding angle of the inductor portion L1 is, for example, 540 degrees (=360+180). The inductor portion L2 includes a portion of the first coil conductor layer 201a located from the connection point 222v with the second connection conductor 222 to the end portion connected to the first connection conductor 221. A winding angle θ2 of the inductor portion L2 is, for example, 60 degrees. In other words, when viewed in the first direction Z, the inductor portion L2 has an arc shape having a central angle θ2 of 60 degrees. The inductor portion L3 includes the entire first coil conductor layer 203a and the entire second coil conductor layer 203b. A winding angle of the inductor portion L3 is, for example, 660 degrees (=360+300). The inductor portion L4 includes the entire first coil conductor layer 202a and a portion of the second coil conductor layer 202b located from a portion connected to the via conductor 202c to the connection point 223v with the third connection conductor 223. A winding angle of the inductor portion L4 is, for example, 420 degrees (=360+60). The inductor portion L5 includes a portion of the second coil conductor layer 202b located from the connection point 223v with the third connection conductor 223 to the end portion connected to the second extended conductor 232. A winding angle θ5 of the inductor portion L5 is, for example, 180 degrees.

With the above configuration, at least partial regions of at least two coils of the plurality of coils 201 to 203 are connected in series to each other, and at least partial regions of at least two coils are connected in parallel to each other. As a result, an inductor component having at least two inductor portions that are connected in series to each other and at least two inductor portions that are connected in parallel to each other is provided. In this way, by using not only the series connection of the coils but also the parallel connection, a wider range of inductance values can be realized. Therefore, it is possible to design the inductor component according to various applications and purposes.

In addition, with the above configuration, by dividing each coil into a plurality of inductor portions having any winding angle, a degree of freedom in design can be further increased.

Further, with the above configuration, it is possible to make the connection between the coils different or to divide one coil into a plurality of inductor portions by disposing the connection conductors. Therefore, inductor components having different inductance values can be easily separately formed.

### Second Modification Example

The inductor component according to the second modification example includes a first coil to a fourth coil. The second modification example is different from the examples shown in FIGS. 22 to 24 in that the third coil and the fourth coil are connected in parallel to each other.

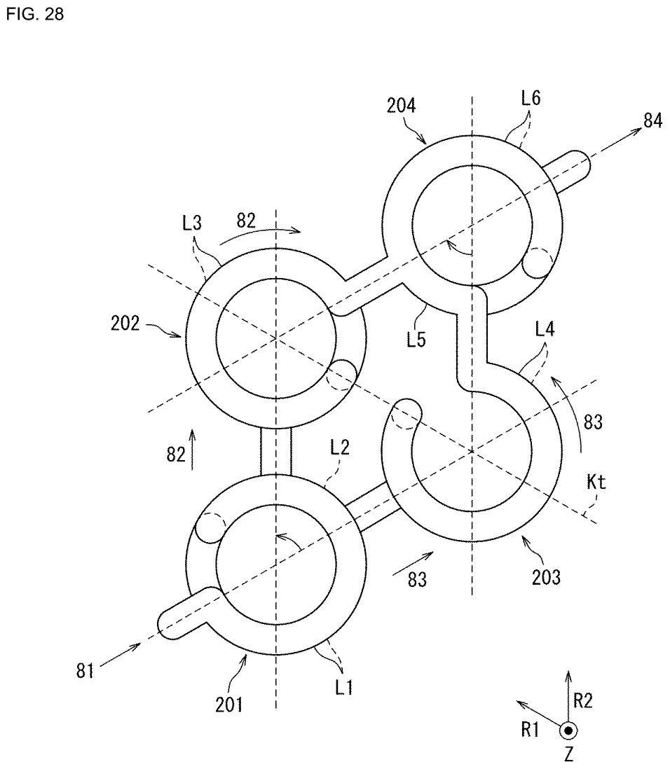

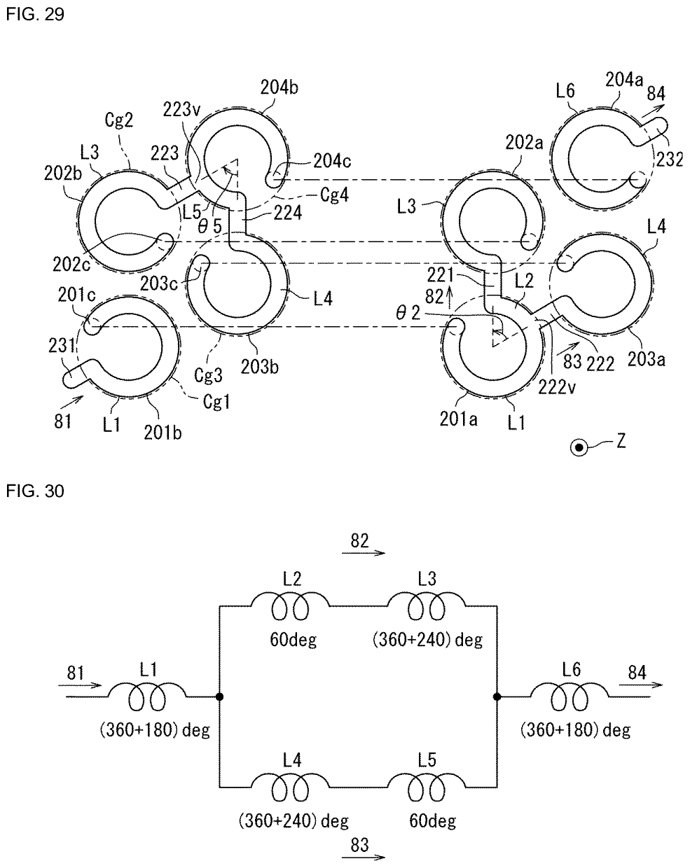

FIG. 28 is a plan view showing a second modification example of the plurality of coils in the inductor component according to the eighth form. FIG. 29 is an exploded plan view of FIG. 28. FIG. 30 is an equivalent circuit diagram of the plurality of coils shown in FIG. 28. Arrows 81 to 84 in FIGS. 28 to 30 illustrate a direction of the current.

As shown in FIGS. 28 and 29, the inductor component according to the present modification example includes a first coil 201 to a fourth coil 204 that are disposed on the same plane in the element body, a first connection conductor 221 to a fourth connection conductor 224 that are disposed in the element body, and a first extended conductor 231 and a second extended conductor 232 that are disposed in the element body. Axes of the first coil 201 to the fourth coil 204 are orthogonal to the plane and are disposed parallel to each other.

The first coil 201 to the fourth coil 204 respectively have first coil conductor layers 204a to 204a, second coil conductor layers 201b to 204b, and via conductors 201c to 204c.

The first connection conductor 221 connects the end portion of the first coil conductor layer 201a of the first coil 201 and the end portion of the first coil conductor layer 202a of the second coil 202. The second connection conductor 222 connects the end portion of the first coil conductor layer 203a of the third coil 203 and the connection point 222v located between both end portions of the first coil conductor layer 201a of the first coil 201. The third connection conductor 223 connects the end portion of the second coil conductor layer 202b of the second coil 202 and a connection point 223v located between both end portions of the second coil conductor layer 204b of the fourth coil 204. The fourth connection conductor 224 connects the end portion of the second coil conductor layer 203b of the third coil 203 and an end portion of the second coil conductor layer 204b of the fourth coil 204.

The first coil 201 to the fourth coil 204 may be disposed such that the centers of the smallest circles thereof form imaginary equilateral triangle lattice points. Each of the first connection conductor to the fourth connection conductor 221 to 224 may extend from an end portion of one coil conductor layer to a part of the other coil conductor layer along any straight line in the equilateral triangle lattice Kt.

The first extended conductor 231 is connected to the end portion of the second coil conductor layer 201b in the first coil 201. The second extended conductor 232 is connected to an end portion of the first coil conductor layer 204a in the fourth coil 204.

As shown in FIGS. 29 and 30, the first coil 201 is divided into an inductor portion L1 and an inductor portion L2 by the second connection conductor 222. The second coil 202 forms an inductor portion L3. The third coil 203 forms an inductor portion L4. The fourth coil 204 is divided into an inductor portion L5 and an inductor portion L6 by the third connection conductor 223.

The inductor portion L2, which is a part of the first coil 201, and the inductor portion L3, which is the second coil 202, are connected in series by the first connection conductor 221. The inductor portion L4, which is the third coil 203, and the inductor portion L5, which is a part of the fourth coil 204, are connected in series by the fourth connection conductor 224. The inductor portions L4 and L5 are connected in parallel to the inductor portions L1 and L2 by the second connection conductor 222 and the third connection conductor 223.

A detailed configuration of each inductor portion will be described. The configurations of the inductor portions L1 and L2 are the same as those in the first modification example. The third inductor portion L3 includes the entire first coil conductor layer 203a and the entire second coil conductor layer 203b. A winding angle of the inductor portion L3 is, for example, 600 degrees (=360+240). The fourth inductor portion L4 includes the entire first coil conductor layer 204a and the entire second coil conductor layer 204b. A winding angle of the inductor portion L4 is, for example, 600 degrees (=360+240). The inductor portion L5 includes a portion of the second coil conductor layer 204b located from the end portion connected to the fourth connection portion 224 to the connection point 223v with the third connection conductor 223. A winding angle θ5 of the inductor portion L5 is, for example, 60 degrees. The inductor portion L6 includes a portion of the second coil conductor layer 204b located from the connection point 223v with the third connection conductor 223 to a portion connected to the via conductor 204c, and the entire first coil conductor layer 204a. A winding angle of the inductor portion L6 is, for example, 540 degrees (=360+180).

FIGS. 22 to 30 show an example in which the diameters of the smallest circles enclosing the plurality of coils are equal to each other, but the diameters of the smallest circles enclosing the coils may be different from each other. In addition, the number of the coils can also be optionally selected. For example, three or more coils may be connected in parallel to each other.

### Ninth Exemplary Aspect

A ninth form is different from the above-described forms in that the plurality of coils are formed by using an S-shaped or reverse S-shaped conductive pattern as a basic unit.

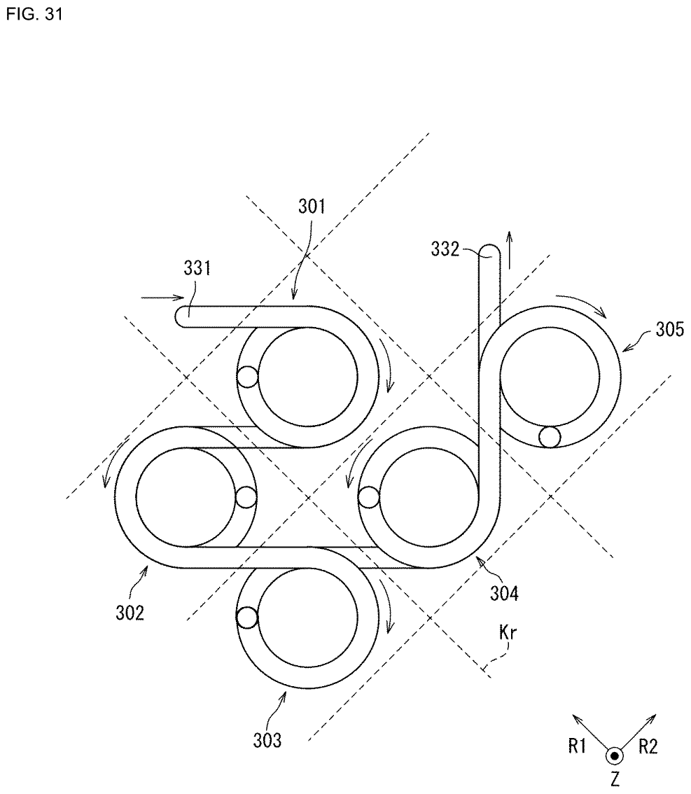

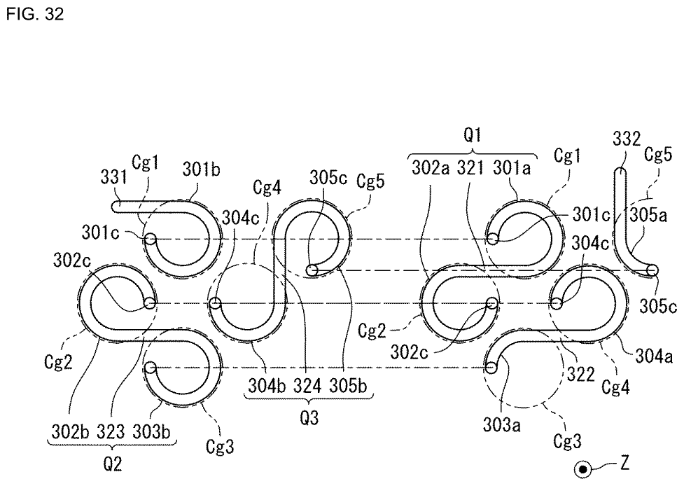

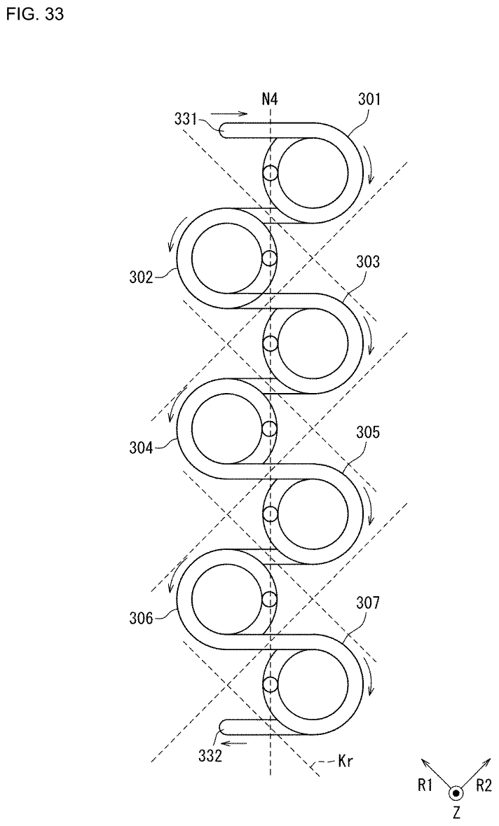

FIG. 31 is a plan view showing a plurality of coils of the inductor component. FIG. 32 is an exploded plan view of FIG. 31.

As shown in FIGS. 31 and 32, the inductor component according to the present form includes a first coil 301 to a fifth coil 305 that are disposed on the same plane in the element body, a first connection conductor 321 to a fourth connection conductor 324 that are disposed in the element body, and a first extended conductor 331 and a second extended conductor 332 that are disposed in the element body. Axes of the first coil 301 to the fifth coil 305 are orthogonal to the plane and are disposed parallel to each other.

The first coil 301 to the fifth coil 305 are connected in series to each other. In this example, as indicated by an arrow in FIG. 31, the current from the first extended conductor 331 flows through the first coil 301 to the fifth coil 305 in this order to the second extended conductor 332.

As shown in FIG. 32, an S-shaped conductive pattern Q1 is disposed in the upper wiring layer. In the lower wiring layer, reverse S-shaped conductive patterns Q2 and Q3 are disposed. Each of the conductive patterns Q1 to Q3 is disposed across two coils.

Each of the conductive patterns Q1 to Q3 includes coil conductor layers of two adjacent coils and a connection conductor between the coil conductor layers. In this example, the conductive pattern Q1 includes a first coil conductor layer 301a of the first coil 301, a first coil conductor layer 302a of the second coil 302, and the first connection conductor 321 that connects the first coil 301 and the second coil 302. The conductive pattern Q2 includes a second coil conductor layer 302b of the second coil 302, a second coil conductor layer 303b of the third coil 303, and the third connection conductor 323 that connects the second coil 302 and the third coil 303. The conductive pattern Q3 includes a fourth coil conductor layer 304b of the fourth coil 304, a second coil conductor layer 305b of the fifth coil 305, and the fourth connection conductor 324 that connects the fourth coil 304 and the fifth coil 305. The connection conductor in each of the conductive patterns Q1 to Q3 is, for example, a portion located between two coil conductor layers defined by the smallest enclosing circle.

With the above-described configuration, in the two adjacent coils in the S-shaped or reverse S-shaped conductive patterns Q1 to Q3, winding directions as viewed in the first direction Z are opposite to each other. Therefore, by using the S-shaped or reverse S-shaped conductive patterns Q1 to Q3 as a basic unit, a structure in which the coils having different winding directions are alternately arranged can be easily realized.

### First Modification Example

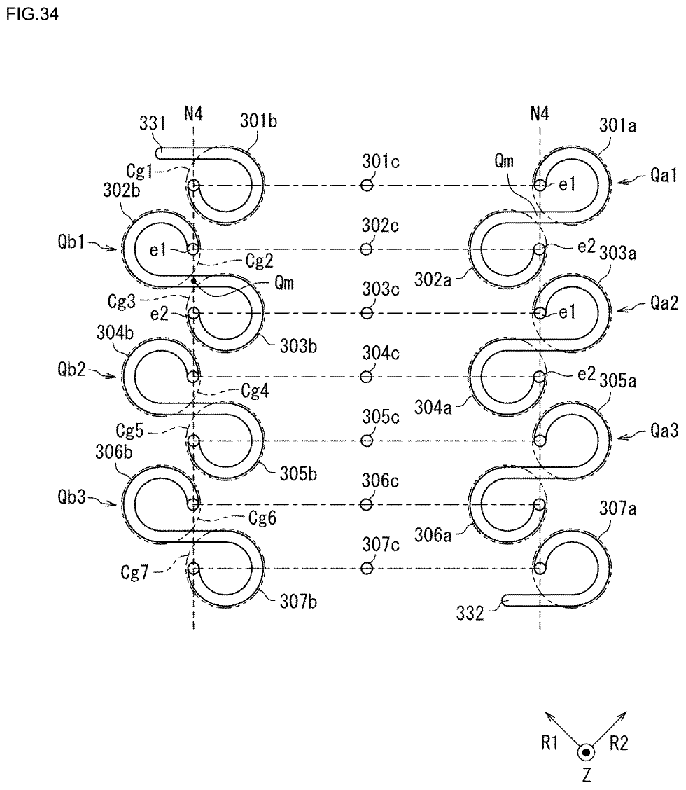

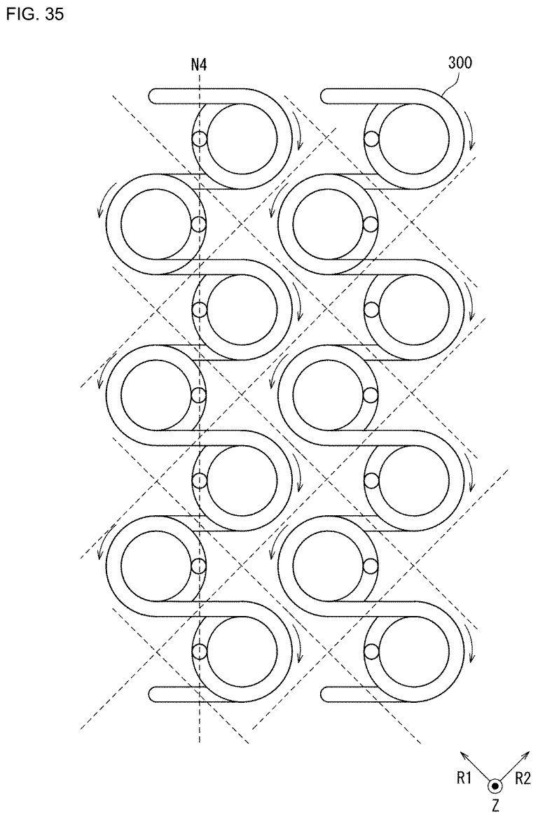

FIG. 33 is a plan view showing a first modification example of the plurality of coils in the ninth form. FIG. 34 is an exploded plan view of FIG. 33. The first modification example is different from the examples shown in FIGS. 31 and 32 in that a plurality of coils arranged in a zigzag shape are configured by the S-shaped or reverse S-shaped conductive pattern.

In the examples shown in FIGS. 33 and 34, a first coil 301 to a seventh coil 307 are arranged in a zigzag shape along an imaginary straight line N4 on the same plane. Winding directions of two adjacent coils are opposite to each other. The first coil 301 to the seventh coil 307 are connected in series to each other. The current flows from the first extended conductor 331 through the first coil 301 to the seventh coil 307 in this order to the second extended conductor 332.

As shown in FIG. 34, reverse S-shaped conductive patterns Qa1 to Qa3 are arranged in the lower wiring layer. When viewed in the first direction Z, centers Qm of the conductive patterns Qa1 to Qa3 are located on the straight line N4, and longitudinal directions of the conductive patterns Qa1 to Qa3 are along the same direction R2. Similarly, S-shaped conductive patterns Qb1 to Qb3 are arranged in the upper wiring layer. When viewed in the first direction Z, centers Qm of the conductive patterns Qb1 to Qb3 are located on the straight line N4, and longitudinal directions of the conductive patterns Qb1 to Qb3 are along a direction R1 intersecting (here, orthogonal to) the direction R2.

Each of the conductive patterns Qb1 to Qb3 in the upper wiring layer is disposed to connect two adjacent conductive patterns in the lower wiring layer. Among two end portions of each of the S-shaped conductive pattern, an end portion e1 located on the first extended conductor 331 side is referred to as a “first end portion”, and an end portion e2 located on the second extended conductor 332 side is referred to as a “second end portion”. For example, when viewed in the first direction Z, the conductive pattern Qb1 is disposed to overlap the first coil conductor layer 302a on the second end portion e2 side of the conductive pattern Qa1 and the first coil conductor layer 303a on the first end portion e1 side of the conductive pattern Qa2. The first end portion e1 of the conductive pattern Qb1 is connected to the second end portion e2 of the conductive pattern Qa1 with a via conductor 302c interposed therebetween. The second end portion e2 of the conductive pattern Qb1 is connected to the first end portion e1 of the conductive pattern Qa2 with a via conductor 303c interposed therebetween.

In the above-described configuration, the plurality of coils 301 to 307 are disposed in a zigzag shape by using the S-shaped or reverse S-shaped conductive pattern as a basic unit. As a result, the number of turns of each coil can be increased as compared with the examples shown in FIGS. 31 and 32. Therefore, for example, the coils 301 to 307 having the number of turns of 1.5 or more can be disposed at a high density. In addition, it is easy to alternately arrange the coils having different winding directions.

In the examples shown in FIGS. 31 to 34, the reverse S-shaped conductive pattern is disposed in the lower wiring layer and the S-shaped conductive pattern is disposed in the upper wiring layer, but the S-shaped conductive pattern may be disposed in the lower wiring layer, and the reverse S-shaped conductive pattern may be disposed in the upper wiring layer. The “S-shaped” conductive pattern also includes, for example, a conductive pattern including the second coil conductor layers 101b and 102b shown in FIG. 4. Similarly, the “reversed S-shape” conductive pattern also includes, for example, a conductive pattern including the first coil conductor layers 102a and 103a shown in FIG. 4. In addition, the connection method of the plurality of coils is not limited to the series connection and may include parallel connection.

### Tenth Exemplary Aspect

In a tenth form, when viewed in the first direction Z, the plurality of coils are disposed in a matrix shape in two directions intersecting each other. A part or an entirety of each coil is connected in series or in parallel to an adjacent coil. Each of the plurality of coils has, for example, a stack structure including a plurality of coil conductor layers.

When viewed in the first direction Z, the inductor component 1 shown in FIG. 3 includes the plurality of coils 102 to 110 that are disposed in a matrix shape in a second direction X and a third direction Y that intersect (here, are orthogonal to) each other.

In the example shown in FIG. 3, the plurality of coils 102 to 110 are arranged at first intervals in the second direction X and are arranged at second intervals in the third direction Y Each of the first interval and the second interval corresponds to, for example, the above-described shortest distances K1 and K2 (FIG. 12). The first interval and the second interval may be equal to each other. In a case where the maximum widths of the plurality of coils in the second direction X and the third direction Y are all equal to each other, an arrangement pitch in the second direction X and an arrangement pitch in the third direction Y may be equal to each other.

When viewed in the first direction Z, the plurality of coils may be arranged in a matrix shape in two directions that intersect obliquely. For example, as shown in FIG. 28, when viewed in the first direction Z, the plurality of coils 201 to 204 may be arranged in a matrix shape in two directions R1 and R2 that intersect each other. The directions R1 and R2 correspond to the second direction X and the third direction Y described above, respectively. The minimum angle formed by the straight line along the second direction R1 and the straight line along the third direction R2 may be, for example, 45 degrees or more and less than 90 degrees (here, 60 degrees).

FIG. 35 is a plan view showing another example of the plurality of coils disposed in a matrix shape. In this example, as in the examples shown in FIGS. 33 and 34, a plurality of coils 300 are formed by using the S-shaped and reverse S-shaped conductive patterns. When viewed in the first direction Z, these coils 300 are arranged in a matrix shape in the second direction R1 and the third direction R2 that intersect (here, orthogonal to) each other. Winding directions of two coils 300 adjacent to each other in the second direction R1 are opposite to each other, and winding directions of two coils 300 adjacent to each other in the third direction R2 are opposite to each other.

With the configuration illustrated in FIG. 3, FIG. 28, and FIG. 30, by disposing the plurality of coils in a matrix shape, the plurality of coils having a suitable coil diameter (for example, a coil diameter having a high inductance value density) can be arranged at a high density.

### Second Exemplary Embodiment

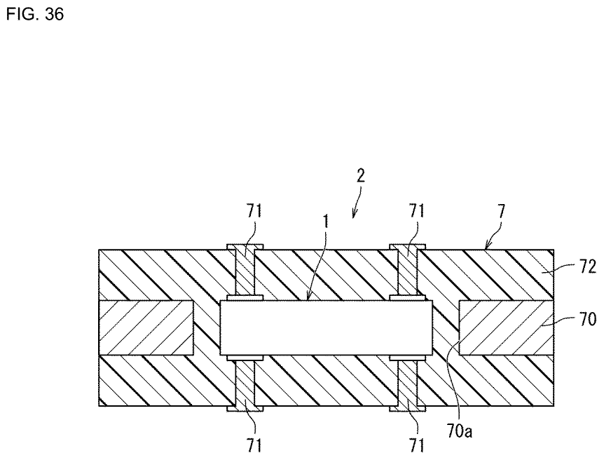

FIG. 36 is a cross-sectional view showing one exemplary embodiment of an inductor component-embedded substrate. As shown in FIG. 22, an inductor component-embedded substrate 2 includes a substrate 7 and an inductor component 1 embedded in the substrate 7. The inductor component 1 has the same configuration as any one of the inductor components described in the first embodiment. In FIG. 36, for convenience, the inductor component 1 is not hatched.

The substrate 7 includes a core material 70, a wiring section 71, and a resin member 72. The inductor component 1 is disposed in a through-hole 70a of the core material 70. The resin member 72 seals the inductor component 1 and the substrate 7. The wiring section 71 is provided to extend through the resin member 72 and is connected to the external conductor of the inductor component 1. The wiring section 71 may be provided in or on the core material 70.

With the above configuration, the inductor component 1 obtains a high inductance value while reducing the thickness while suppressing the deterioration in the performance is provided, so that the inductor component-embedded substrate 2 can be thinned while suppressing the deterioration in the performance of the inductor component-embedded substrate 2.

The inductor component 1 and the inductor component-embedded substrate 2 according to the present disclosure can cope with a large current and can be thinner than in the related art. The inductance value can be adjusted to a desired value by using the series connection or the parallel connection of the plurality of coils. Therefore, for example, the inductor component can be suitably applied as a power inductor used in a power supply circuit, particularly as a power inductor used in an output unit of a DC-DC converter of a switching system.

The present disclosure is not limited to the above-described exemplary embodiments, and can be modified as appropriate without departing from the scope of the present disclosure. For example, the feature points of the first and second embodiments may be combined in various ways. The number of the coils or the number of the connection conductors can be increased or decreased as desired.

The present disclosure includes the following exemplary aspects.

According to some exemplary aspects, an inductor component includes: an element body including a magnetic layer; a first coil and a second coil that are disposed on the same plane in the element body and are adjacent to each other; and a first connection conductor that connects the first coil and the second coil, in which an axis of the first coil and an axis of the second coil are orthogonal to the plane and are disposed parallel to each other, and when viewed in a first direction orthogonal to the plane, a shortest distance between the first coil and the second coil is equal to or greater than a largest wiring width among a wiring width of the first coil and a wiring width of the second coil, and is equal to or less than an average value of a diameter of a smallest circle enclosing the first coil and a diameter of a smallest circle enclosing the second coil.

According to some exemplary embodiments, the first coil and the second coil each have a first coil conductor layer and a second coil conductor layer stacked in the first direction on the first coil conductor layer and electrically connected to the first coil conductor layer. The first coil conductor layers of the first coil and the second coil are disposed in the same layer, and the second coil conductor layers of the first coil and the second coil are disposed in the same layer. The first connection conductor is connected in the same layer as the first coil conductor layers of the first coil and the second coil, or is connected in the same layer as the second coil conductor layers of the first coil and the second coil.

According to some exemplary embodiments, when viewed in the first direction, the first connection conductor is located in a region surrounded by a first smallest enclosing circle that is the smallest circle enclosing the first coil, a second smallest enclosing circle that is the smallest circle enclosing the second coil, a first common external tangent that is tangent to the first smallest enclosing circle and the second smallest enclosing circle, and a second common external tangent that is tangent to the first smallest enclosing circle and the second smallest enclosing circle.

According to some exemplary embodiments, when viewed in the first direction, the first connection conductor is provided at such a position that the first connection conductor has the shortest distance.

According to some exemplary embodiments, the first coil and the second coil each have a first coil conductor layer and a second coil conductor layer stacked in the first direction on the first coil conductor layer and electrically connected to the first coil conductor layer. When viewed in the first direction, the first coil conductor layer and the second coil conductor layer of the first coil each have an arc shape provided in a range where a central angle is 180° or more and 355° or less, and the first coil conductor layer and the second coil conductor layer of the second coil each have an arc shape provided in a range where a central angle is 180° or more and 355° or less.

According to some exemplary embodiments, when viewed in the first direction, a smallest circle enclosing the first coil conductor layer of the first coil and a smallest circle enclosing the first coil conductor layer of the second coil do not overlap each other. A smallest circle enclosing the second coil conductor layer of the first coil and a smallest circle enclosing the second coil conductor layer of the second coil do not overlap each other.

According to some exemplary embodiments, the inductor component includes a plurality of coils including at least the first coil and the second coil. The plurality of coils are disposed on the plane and are connected in series to each other to form one inductor group. The plurality of coils each have a plurality of coil conductor layers stacked in the first direction. In each of the plurality of coils, the number of all the coil conductor layers included in one coil is smaller than the number of all the coil conductor layers included in the inductor group.

According to some exemplary embodiments, at least a part of the first coil and at least a part of the second coil are connected in parallel.

According to some exemplary embodiments, the inductor component includes a plurality of coils including the first coil and the second coil on the plane. Axes of the plurality of coils are parallel to each other, at least partial regions of at least two coils of the plurality of coils are connected in series to each other, and at least partial regions of at least two coils of the plurality of coils are connected in parallel to each other.

According to some exemplary embodiments, when viewed in the first direction, the first coil and the second coil are wound in opposite directions.

According to some exemplary embodiments, a third coil is disposed on the plane in the element body and is adjacent to the second coil; and a second connection conductor connects the second coil and the third coil. The axis of the second coil and an axis of the third coil are orthogonal to the plane and are disposed parallel to each other. When viewed in the first direction, a shortest distance between the second coil and the third coil is equal to or greater than a largest wiring width among the wiring width of the second coil and a wiring width of the third coil, and is equal to or less than an average value of the diameter of the smallest circle enclosing the second coil and a diameter of a smallest circle enclosing the third coil.

According to some exemplary embodiments, when viewed in the first direction, imaginary square lattice points are defined in which a line segment connecting a center of the smallest circle enclosing the first coil and a center of the smallest circle enclosing the second coil is used as one side, and a center of the smallest circle enclosing the third coil is located inside an imaginary circle that is centered on the square lattice point and of which a diameter is half of an average value of the diameter of the smallest circle enclosing the first coil, the diameter of the smallest circle enclosing the second coil, and the diameter of the smallest circle enclosing the third coil.

According to some exemplary embodiments, when viewed in the first direction, imaginary equilateral triangle lattice points are defined in which a line segment connecting a center of the smallest circle enclosing the first coil and a center of the smallest circle enclosing the second coil is used as one side, and a center of the smallest circle enclosing the third coil is located inside an imaginary circle that is centered on the equilateral triangle lattice point and of which a diameter is half of an average value of the diameter of the smallest circle enclosing the first coil, the diameter of the smallest circle enclosing the second coil, and the diameter of the smallest circle enclosing the third coil.

According to some exemplary embodiments, the second coil has a first coil conductor layer, a second coil conductor layer stacked in the first direction on the first coil conductor layer, and a via conductor that extends in the first direction and connects the first coil conductor layer and the second coil conductor layer, and when viewed in the first direction, a straight line connecting a center of the smallest circle enclosing the first coil and a center of the smallest circle enclosing the second coil is defined as a first straight line, a straight line connecting the center of the smallest circle enclosing the second coil and a center of the smallest circle enclosing the third coil is defined as a second straight line, a straight line that bisects an angle formed by the first straight line and the second straight line is defined as a third straight line, and the via conductor overlaps the third straight line.

According to some exemplary embodiments, the inductor component includes a plurality of coils including at least the first coil and the second coil, the plurality of coils are disposed on the plane and are connected in series to each other to form one inductor group, and when viewed in the first direction, assuming that an average value of diameters of smallest circles enclosing the coils is a first reference value and an average value of wiring widths of the coils is a second reference value, in a case where a first reference coil that has a smallest enclosing circle of which a diameter is 0.5 times the first reference value and which has a wiring width equal to the second reference value is defined, and a second reference coil that has a smallest enclosing circle of which a diameter is 2 times the first reference value and which has a wiring width equal to the second reference value is defined, an inductance value per unit area of each coil is larger than an inductance value per unit area of the first reference coil, and is larger than an inductance value per unit area of the second reference coil.

According to some exemplary embodiments, the inductor component includes a plurality of coils including the first coil and the second coil on the plane, axes of the plurality of coils are parallel to each other, the plurality of coils each have a first coil conductor layer and a second coil conductor layer stacked in the first direction on the first coil conductor layer and electrically connected to the first coil conductor layer, and when viewed in the first direction orthogonal to the plane, the plurality of coils are arranged in a matrix shape in a second direction and a third direction intersecting the second direction.

According to some exemplary embodiments, when viewed in the first direction, two coils adjacent to each other in the second direction are wound in opposite directions, and two coils adjacent to each other in the third direction are wound in opposite directions.

Some exemplary aspects of the disclosure provide an inductor component-embedded substrate including a substrate and the inductor component, which is embedded in the substrate.

### REFERENCE SIGNS LIST

1, 1A Inductor component
2 Inductor component-embedded substrate
7 Substrate
10 Element body
11 to 14 First to fourth magnetic layers
16 to 18 First to third insulating layers
21 to 27 First to seventh external conductors
31 to 36 First to sixth columnar conductors
41 to 46 First to sixth via conductors
101 to 112 First to twelfth coils
101A, 101B First coil
102A, 102B Second coil
101a to 112a First coil conductor layer
101b to 112b Second coil conductor layer
101c to 112c Via conductor
101d, 102d Third coil conductor layer
101e, 102e Fourth coil conductor layer
121 to 129 First to ninth connection conductors
121A, 121B First connection conductor
121a First portion
121b Second portion
121c Via portion
131 to 136 First to sixth extended conductors
141 to 143 First to third inductor groups
201 to 204 First to fourth coils
221 to 224, 321 to 324 First to fourth connection conductors
231 and 232, 321 and 322 First and second extended conductors
301 to 307 First to seventh coils
201a to 204a, 301a to 307a First coil conductor layer
201b to 204b, 301b to 307b Second coil conductor layer
201c to 204c, 301c to 304c Via conductor
AX1, AX2, AX3 First, second, and third axes
Cg1, Cg2, Cg3 First, second, and third smallest enclosing circles
Ck Imaginary circle
Cα1, Cα2 First and second smallest enclosing circles
Cβ1, Cβ2 First and second smallest enclosing circles
D1, D2, D3 First, second, and third diameters
K1, K2 First and second shortest distances
Kr Square lattice
Kt Equilateral triangle lattice
L1 to L6 Inductor portion
M1, M2, M3 First, second, and third centers
N1, N2, N3 First, second, third straight lines
P Lattice point
Q1 to Q3, Qa1 to Qa3, Qb1 to Qb3 Conductive pattern
S Line segment
T1, T2 First and second common external tangents
U Region
W1, W2, W3 First, second, and third wiring widths
Z First direction
α1, α2 First and second central angles
β1, B2 First and second central angles

What is claimed is:

1. An inductor component comprising:
an element body including a magnetic layer;
a first coil and a second coil that are disposed on a plane in the element body and are adjacent to each other; and
a first connection conductor that connects the first coil to the second coil, wherein a first axis of the first coil and a second axis of the second coil are disposed parallel to each other in a first direction that is orthogonal to the plane; and
wherein a shortest distance between the first coil and the second coil is equal to or greater than a larger of a wiring width of a first wiring width of the first coil and a second wiring width of the second coil, and is equal to or less than an average value of a first diameter of a first smallest circle enclosing the first coil and a second diameter of a second smallest circle enclosing the second coil.

2. The inductor component according to claim 1, wherein:
the first coil and the second coil each have a first coil conductor layer and a second coil conductor layer stacked in the first direction on the first coil conductor layer and electrically connected to the first coil conductor layer;
the first coil conductor layers of the first coil and the second coil are disposed in a same first conductor layer, and the second coil conductor layers of the first coil and the second coil are disposed in a same second conductor layer; and
the first connection conductor is in a same layer as the first coil conductor layers of the first coil and the second coil to connect the first coil to the second coil, or is in a same layer as the second coil conductor layers of the first coil and the second coil to connect the first coil to the second coil.

3. The inductor component according to claim 1, wherein the first connection conductor is located in a region surrounded by the first smallest enclosing circle that encloses the first coil, the second smallest enclosing circle that encloses the second coil, a first common external tangent line to the first smallest enclosing circle and the second smallest enclosing circle, and a second common external tangent line to the first smallest enclosing circle and the second smallest enclosing circle.

4. The inductor component according to claim 1, wherein the first connection conductor is configured to connect the first coil and the second coil at a position with a shortest distance between the first coil and the second coil.

5. The inductor component according to claim 1, wherein:
the first coil and the second coil each have a first coil conductor layer and a second coil conductor layer stacked in the first direction on the first coil conductor layer and electrically connected to the first coil conductor layer;
the first coil conductor layer and the second coil conductor layer of the first coil each have an arc shape with a central angle of 180° or more and 355° or less; and
the first coil conductor layer and the second coil conductor layer of the second coil each have an arc shape with a central angle of 180° or more and 355° or less.

6. The inductor component according to claim 5, wherein:
a smallest circle enclosing the first coil conductor layer of the first coil and a smallest circle enclosing the first coil conductor layer of the second coil do not overlap each other; and
a smallest circle enclosing the second coil conductor layer of the first coil and a smallest circle enclosing the second coil conductor layer of the second coil do not overlap each other.

7. The inductor component according to claim 1, further comprising a plurality of coils including at least the first coil and the second coil that are disposed on the plane and are connected in series to form an inductor group;
wherein the plurality of coils each have a plurality of coil conductor layers stacked in the first direction; and
a number of coil conductor layers in each of the plurality of coils is smaller than a total number of coil conductor layers in the inductor group.

8. The inductor component according to claim 1, wherein at least a part of the first coil and at least a part of the second coil are connected in parallel.

9. The inductor component according to claim 1, further comprising a plurality of coils including the first coil and the second coil on the plane, wherein:
axes of the plurality of coils are parallel to each other;
at least two coils of the plurality of coils are partially connected in series; and
at least two coils of the plurality of coils are partially connected in parallel.

10. The inductor component according to claim 1, wherein the first coil and the second coil are wound in opposite directions.

11. The inductor component according to claim 1, further comprising:
a third coil that is disposed on the plane in the element body and is adjacent to the second coil; and
a second connection conductor that connects the second coil and the third coil, wherein:
the second axis of the second coil and a third axis of the third coil are orthogonal to the plane and are disposed parallel to each other, and
a shortest distance between the second coil and the third coil is equal to or greater than a larger wiring width of the second wiring width of the second coil and a third wiring width of the third coil, and is equal to or less than an average value of the second diameter of the second smallest circle enclosing the second coil and a third diameter of a third smallest circle enclosing the third coil.

12. The inductor component according to claim 11, wherein:
a first center of the first smallest circle enclosing the first coil and a second center of the second smallest circle enclosing the second coil are respectively located at a first square lattice point and a second square lattice point that are adjacent square lattice points of an imaginary square lattice; and
a third center of the third smallest circle enclosing the third coil is located inside an imaginary circle centered on a third square lattice point of the imaginary square lattice, and a diameter of the imaginary circle is half of an average value of the first diameter of the first smallest circle enclosing the first coil, the second diameter of the second smallest circle enclosing the second coil, and the third diameter of the third smallest circle enclosing the third coil.

13. The inductor component according to claim 11, wherein:
a first center of the first smallest circle enclosing the first coil and a second center of the second smallest circle enclosing the second coil are respectively located at a first equilateral triangle lattice point and a second equilateral triangle lattice point that are adjacent lattice equilateral triangle points of an imaginary equilateral triangle lattice; and
a third center of the third smallest circle enclosing the third coil is located inside an imaginary circle centered on a third equilateral triangle lattice point, a diameter of the imaginary circle being half of an average value of the first diameter of the first smallest circle enclosing the first coil, the second diameter of the second smallest circle enclosing the second coil, and the third diameter of the third smallest circle enclosing the third coil.

14. The inductor component according to claim 11, wherein:
the second coil has a first coil conductor layer, a second coil conductor layer stacked in the first direction on the first coil conductor layer, and a via conductor that extends in the first direction and connects the first coil conductor layer to the second coil conductor layer; and
the via conductor is positioned on a line that bisects an angle formed by a first straight line connecting a first center of the first smallest circle enclosing the first coil and a second center of the second smallest circle enclosing the second coil, and a second straight line connecting the second center of the second smallest circle enclosing the second coil and a third center of the third smallest circle enclosing the third coil.

15. The inductor component according to claim 1, further comprising a plurality of coils including at least the first coil and the second coil, wherein:
the plurality of coils are disposed on the plane and are connected in series to form an inductor group; and
an inductance value per unit area of each coil of the plurality of coils is larger than a first inductance value per unit area of a first reference coil, and is larger than a second inductance value per unit area of a second reference coil, the first reference coil having a first reference smallest enclosing circle of a first reference diameter equal to 0.5 times of a first reference value and having a first reference wiring width equal to a second reference value, the second reference coil having a second smallest enclosing circle of a second reference diameter equal to 2 times of the first reference value and having a second reference wiring width equal to the second reference value, the first reference value being a first average value of diameters of smallest circles respectively enclosing the plurality of coils, the second reference value being a second average value of wiring widths of the plurality of coils.

16. The inductor component according to claim 1, further comprising a plurality of coils including the first coil and the second coil on the plane, wherein:
axes of the plurality of coils are parallel to each other,
the plurality of coils each have a first coil conductor layer and a second coil conductor layer stacked in the first direction on the first coil conductor layer and electrically connected to the first coil conductor layer; and
the plurality of coils are arranged in a matrix shape in the plane in a second direction and a third direction intersecting the second direction.

17. The inductor component according to claim 16, wherein two adjacent coils in the second direction are wound in opposite directions, and two adjacent coils in the third direction are wound in opposite directions.

18. An inductor component-embedded substrate comprising:
a substrate; and
an inductor component that is embedded in the substrate and that includes:
an element body including a magnetic layer;
a first coil and a second coil that are disposed on a plane in the element body and are adjacent to each other; and
a first connection conductor that connects the first coil to the second coil, wherein:
a first axis of the first coil and a second axis of the second coil are disposed parallel to each other in a first direction that is orthogonal to the plane; and
a shortest distance between the first coil and the second coil is equal to or greater than a larger wiring width of a first wiring width of the first coil and a second wiring width of the second coil, and is equal to or less than an average value of a first diameter of a first smallest circle enclosing the first coil and a second diameter of a second smallest circle enclosing the second coil.

19. The inductor component-embedded substrate according to claim 18, wherein:
the first coil and the second coil each have a first coil conductor layer and a second coil conductor layer stacked in the first direction on the first coil conductor layer;
the respective first coil conductor layers of the first coil and the second coil are disposed in a first conductor layer, and the respective second coil conductor layers of the first coil and the second coil are disposed in a second conductor layer; and
the first connection conductor is in the first conductor layer as the first coil conductor layers of the first coil and the second coil to connect the first coil to the second coil, or is in the second conductor layer as the second coil conductor layers of the first coil and the second coil to connect the first coil to the second coil.

20. The inductor component-embedded substrate according to claim 18, wherein the first connection conductor is configured to connect the first coil and the second coil at a position with a shortest distance between the first coil and the second coil.
